(19) United States
(12) Patent Application Publication
(10) Pub. No.: US 2025/0272590 A1
(43) Pub. Date: Aug. 28, 2025

(54) SUPERCONDUCTING QUANTUM CIRCUIT APPARATUS

(71) Applicant: NEC Corporation, Tokyo (JP)

(72) Inventors: Yoshihito HASHIMOTO, Tokyo (JP); Tsuyoshi YAMAMOTO, Tokyo (JP); Yohei KAWAKAMI, Tokyo (JP)

(73) Assignee: NEC Corporation, Tokyo (JP)

(21) Appl. No.: 19/052,437

(22) Filed: Feb. 13, 2025

(30) Foreign Application Priority Data
Feb. 28, 2024 (JP) 2024-028785

(51) Int. Cl. G06N 10/40

(52) U.S. Cl. CPC G06N 10/40

(57) ABSTRACT

A superconducting quantum circuit apparatus includes a qubit; and a first wiring with a wiring used as a transmission of a signal to generate a magnetic flux to be applied to the qubit and a wiring used as a transmission of a signal input by capacitive coupling to and/or output, by capacitive coupling from the qubit, combined together thereinto, as a single wiring.

### CROSS REFERENCE TO RELATED APPLICATIONS

This application is based upon and claims the benefit of the priority of Japanese patent application No. 2024-028785, filed on Feb. 28, 2024, the disclosure of which is incorporated herein in its entirety by reference thereto.

The disclosure relates to a superconducting quantum circuit apparatus.

### BACKGROUND

In recent years, research and development of quantum computers have been conducted worldwide. There are various quantum computer technologies, one of which is a superconducting quantum computer using superconducting elements. As a quantum bit (qubit) using a superconducting element(s), a Josephson parametric oscillator including, for example, a SQUID (Superconducting Quantum Interference Device) is known (e.g., PTL (Patent Literature) 1). A superconducting quantum computer that combines multiple qubits to perform quantum computation, may be configured to include an input/output line(s) for reading out a state(s) of a qubit(s) and a control line(s) for adjusting a resonance frequency of each of qubits. A frequency-variable coupler including, for example, a SQUID(s), is known as a coupler configured to combine multiple qubits. The frequency-variable coupler may be configured to include an input/output line for reading out a state of the coupler and a control line (also called “a flux bias line”) for adjusting a resonance frequency of the coupler.

PTL 1: Japanese Unexamined Patent Application Publication No. 2018-11022

### SUMMARY

In a superconducting quantum computer with superconducting quantum circuit(s) including an array of qubits and couplers integrated thereon, as the number of qubits and couplers increases, the total number of necessary signal lines, control lines and other wiring increases significantly, thus making implementation thereof difficult.

One of the purposes of the present disclosure is to provide a superconducting quantum circuit enabling a reduction in the number of wirings for qubits and/or couplers.

According to one aspect of the present disclosure, a superconducting quantum circuit apparatus includes a qubit, and a first wiring with a wiring used as a transmission of a signal to generate a magnetic flux to be applied to the qubit and a wiring used as a transmission of a signal input by capacitive coupling to and/or output, by capacitive coupling from the qubit combined together thereinto as a single wiring.

According to one further aspect of the present disclosure, a superconducting quantum circuit includes a plurality of qubits, a coupler mutually coupling the plurality of qubits, and a second wiring with a wiring used as a transmission of a signal to generate a magnetic flux to be applied to the qubit and a wiring used as a transmission of a signal input by capacitive coupling to and/or output, by capacitive coupling from the coupler combined together thereinto as a single wiring.

According to the present disclosure, it is possible to provide a qubit and/or a coupler that enables a reduction in the number of wirings.

### BRIEF DESCRIPTION OF DRAWINGS

FIG. 1 is a diagram illustrating a circuit configuration of a qubit of one of comparative examples.

FIG. 2 is a diagram illustrating a qubit of one of comparative examples.

FIGS. 3A and 3B are diagrams illustrating an example layout of a qubit of comparative examples and a schematic plan view of an area close to SQUID of the qubit.

FIG. 4 is a diagram illustrating a circuit configuration of an example qubit of at least one of example embodiments in the present disclosure.

FIGS. 5A and 5B are diagrams illustrating an example of a bias T circuit and a diplexer.

FIGS. 6A and 6B are schematic plans illustrating an example layout of a qubit of at least one of example embodiments in the present disclosure and an enlarged view of an area close to SQUID

FIG. 7 illustrates a circuit configuration corresponding to the layout in FIG. 6B.

FIG. 8 illustrates a circuit configuration of a coupler of a comparative example.

FIGS. 9A and 9B are schematic plan views of an example layout of a coupler of comparative examples and an enlarged view of an area close to SQUID.

FIG. 10 is a diagram illustrating a circuit configuration of an example of a coupler of at least one of example embodiments according to the present disclosure.

FIGS. 11A and 11B are diagrams illustrating an example layout of a coupler of the present disclosure and a schematic plan view of an area close to SQUID, enlarged.

FIG. 12 illustrates an example of an air bridge.

FIG. 13 is a diagram illustrating a circuit configuration of one of several variations of a qubits according to the present disclosure.

FIG. 14 is a schematic plan view of an enlarged area close to SQUID of FIG. 13.

FIG. 15 is a diagram illustrating a circuit configuration of one of other qubits of some variations of a qubit of the present disclosure.

FIG. 16 is a diagram illustrating a circuit configuration of one more qubit of some variants of the qubits of the present disclosure.

FIG. 17 is a diagram illustrating a circuit configuration of one more qubit of some variants of the qubits of the present disclosure.

FIG. 18 is a diagram illustrating a circuit configuration of one other coupler of some variants of the qubits of the present disclosure.

FIG. 19 is a diagram illustrating a circuit configuration of one more coupler of some variants of the qubits of the present disclosure.

FIG. 20 is a diagram illustrating a circuit configuration of one more coupler of some variants of the qubits of the present disclosure.

FIG. 21 is a diagram illustrating a circuit configuration of one more coupler of some variants of the qubits of the present disclosure.

FIG. 22 is a diagram illustrating schematically a quantum computer (annealing machine).

FIG. 23 is a diagram illustrating schematically a n example of the connection between a coupler and a qubit of the present disclosure.

FIG. 24 is a diagram illustrating schematically another example of the connection configuration of the present disclosure.

FIG. 25 is a diagram illustrating schematically another example of the connection configuration of the present disclosure.

### EXAMPLE EMBODIMENTS

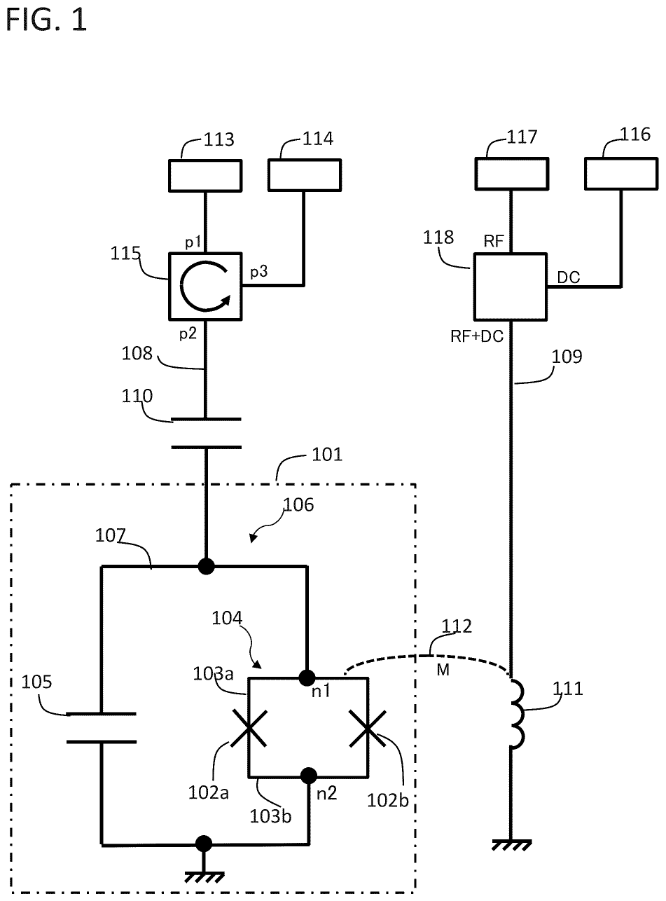

The following describes example embodiments of the present disclosure. First, a comparative example will be used to explain a qubit, as a premise of the present disclosure. The comparative example is intended to illustrate one of the issues in detail, that is, increase in the number of qubits and couplers accompanied with significant increase in the total number of necessary signal lines, control lines and other wirings. FIG. 1 illustrates a comparative example of a qubit which uses a Josephson parametric oscillator. Referring to FIG. 1, a qubit 101 includes a SQUID 104 in which a first Josephson junction 102a and a second Josephson junction 102b are connected in a loop with a first superconducting member 103a and a second superconducting member 103b. A site (indicated by an X) where one end of the first superconducting member 103a and one end of the second superconducting member 103b are coupled through an insulating layer (tunnel insulating layer) not shown corresponds to the first Josephson junction 102a. A site (indicated by an X) where the other end of the first superconducting member 103a and the other end of the second superconducting member 103b are coupled through the tunnel insulation layer not shown corresponds to the second Josephson junction 102b. The first Josephson junction 102a and the second Josephson junction 102b are connected in parallel to two paths on the left and right between one end (node n1) and the other end (node n2) of the SQUID 104 which is connected to ground. A capacitance 105 is connected between the one end (node n1) of the SQUID 104 and ground. The capacitance 105 is a shunt capacitor connected in parallel to the SQUID 104 between electrode 107 and ground. A SQUID is generally a closed circuit consisting of N (Nis a predetermined integer greater than or equal to 1) Josephson junction(s) connected in a ring with superconducting members. One that includes a Josephson junction in each of the two paths between nodes n1 and n2 may be called a dc-SQUID, while one with a single Josephson junction may be called an rf-SQUID. FIG. 1 illustrates a configuration of the SQUID 104 with two Josephson junctions connected in parallel, but the number of Josephson junctions in the loop of the SQUID may be arbitrary.

For the qubit 101, there are provided two wirings, an input-output line 108 and a control line 109. The input-output line 108 is made of an input line for initializing a state of the qubit 101 and an output line (read-out line) for reading out the state of the qubit 101 configured in a single wiring (e.g., made of superconducting material). One end of the input-output line 108 is connected to an electrode 107 of the qubit 101 via a coupling capacitance 110. It is noted that the coupling capacitance 110 is not made of a specific capacitor element between one end of the input-output line 108 and the electrode 107 of the qubit 101 but corresponds to a capacitance between one end of the input-output line 108 and the electrode 107 of the qubit 101 opposed thereto, on a substrate.

The input-output line 108 is used for signal-input to and/or signal-output from qubit 101. The signal from qubit 101 may be a signal output from qubit 101 or a signal which is inputted to the qubit 101 and returned to the input-output line 108. An input-output signal on the input-output line 108 may be used for calibration of the qubit 101, as well as for arithmetic operation by the qubit 101.

The control line 109 is used to transmit a signal to generate a magnetic flux applied to the qubit 101. More specifically, one end of the control line 109 is connected to ground via an inductor 111. During operation of the qubit 101, the inductor 111 is inductively coupled (also referred to as “inductive coupling”) to the SQUID 104. Electromagnetic inductive coupling between the inductor 111 and the SQUID 104 is represented by a mutual inductance 112. Current supplied to the control line 109 from outside flows through the inductor 111 to the ground side. Current flowing through the inductor 111 generates a magnetic flux, which penetrates the SQUID 104. A resonance frequency of the resonator 106 can be adjusted by applying a DC current to the control line 109. By applying an alternating current (also called “pump wave”) to the control line 109, the qubit 101 oscillates parametrically with an oscillation output signal (half the frequency of the pump wave) output to the input-output line 108. A phase of the output signal depends on an oscillation state of the qubit 101. The oscillation state is also controlled by the input signal from the input-output line 108.

The other end of the input-output line 108 is connected to a signal source 113 and an instrumentation 114 via a circulator 115. The other end of the control line 109 is connected to a DC power supply 116 and an AC power supply 117 via a bias T circuit 118. The qubit 101 is placed in an refrigerator not shown and operates in a state cooled to an extremely low (cryogenic) temperature. The signal source 113, measuring instrumentation 114, DC power supply 116, and AC power supply 117 are located in a room temperature environment outside the refrigerator not shown. When the qubit 101 is operating, a signal from the signal source 113 outside the refrigerator not shown is transmitted through a coaxial cable (not shown) provided inside the refrigerator, attenuated in stages by attenuators (not shown) installed at each temperature stage, transmitted through the circulator 115 to the input/output line 108, and input to the qubit 101. A signal output from the qubits 101 and a reflected signal are transmitted from the input/output line 108 through the circulator 115 to an unshown low-pass filter, bandpass filter, isolator, or amplifier (such as a HEMT (High Electron Mobility Transistor amplifier), etc., and then transmitted to the measuring instrument 114 outside the refrigerator. An AC signal (microwave) from the AC power supply unit 117 is transmitted through a coaxial cable not shown or the like provided inside the refrigerator, attenuated in steps by attenuators (not shown) installed at each temperature stage, and input to an RF (Radio Frequency) port of a bias T circuit 118. A DC signal from the DC power supply 116 is transmitted by a transmission line not shown or the like inside the refrigerator and is supplied to the DC port of the bias T circuit 118 via a low-pass filter not shown.

There may be provided a chip (not shown) including the qubit 101 and the coupler 201, which are to be described later, on a wiring layer, a wiring chip (interposer) both not shown to be mounted by joining the chip, for example, face-down, and a printed circuit board not shown to mount the wiring chip (interposer). It may be configured to connect to a port 2 (p2) of the circulator 115 via a cable member (e.g., coaxial cable) that is connected to a connector on the printed circuit board.

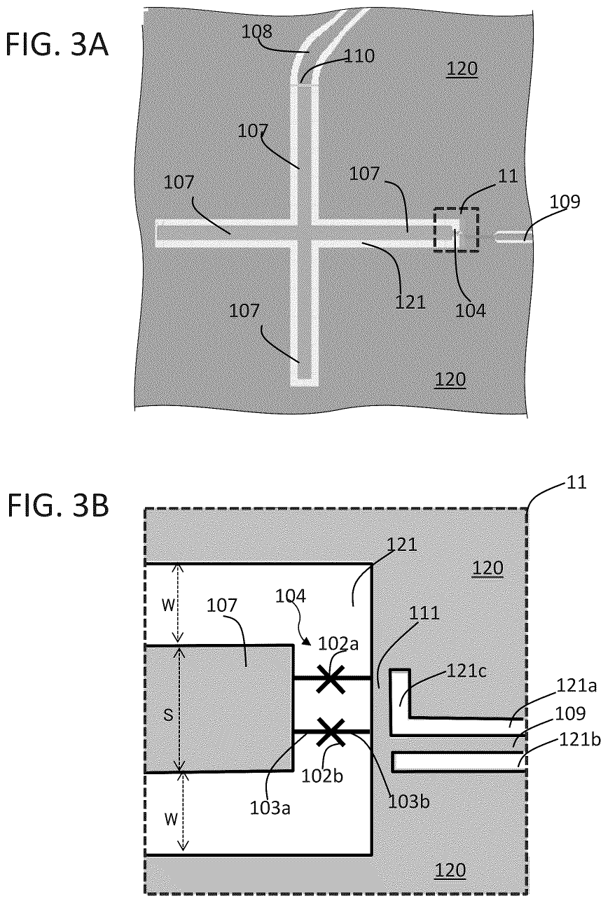

In FIG. 1, the bias T circuit 118 is configured as shown in FIG. 3A, for example, to superimpose a modulated current (AC current) on a DC current. An AC current from the AC power supply 117 is supplied to the RF port of the bias T circuit 118, and a current in which the AC current is superimposed on the DC current is output from the RF+DC port of the bias T circuit 118 to the control line 109. The current (DC current+AC current) output to the control line 109 flows into the inductor 111, generating a magnetic field, which penetrates the loop of the SQUID 104. This magnetic field is a vector addition (superposition) of a DC bias magnetic field (DC bias magnetic flux) corresponding to the DC current flowing in the inductor 111 and an AC magnetic field (AC magnetic flux) corresponding to the AC current superimposed on that DC current.

In the qubit 101, the resonance frequency of the resonator 106 varies depending on a value of a magnetic flux penetrating the SQUID 104. When a value of the DC current output from the DC power supply 116 is changed, the value of the magnetic flux Φ through the SQUID 104 changes. The magnetic flux Φ penetrating the loop of the SQUID 104 is assumed to be an integer multiple of the magnetic flux quantum Φ0. When modulated at a frequency approximately twice the resonance angular frequency ω0 of the resonator 106 of the qubit 101 with a DC magnetic field applied thereto, an oscillation amplitude of the resonator 106 of the qubit 101 increases, and a signal intensity on the control line 109 increases. When the signal intensity on the control line 109 exceeds a threshold value, oscillation occurs, and even if the signal on control line 109 does not exist, the resonator 106 oscillates and outputs a signal with a resonance angular frequency ω0.

The resonator 106 of the qubit 101 can be regarded as a nonlinear resonant circuit with the capacitance 105 and SQUID 104 as a nonlinear inductor. An equivalent inductance of the loop of the SQUID 104 depends on a magnitude of a magnetic flux Φ through the loop of the SQUID 104. The magnitude of the magnetic flux Φ through the loop of the SQUID 104 depends on a magnitude of a current flowing in the inductor 111. Therefore, a resonance frequency of the resonator 106 of the qubit 101 varies with a magnitude of the current flowing through the inductor 111.

If the two Josephson junctions 102a and 102b of the SQUID 104 have the same critical current value Ic, the total current I flowing in the SQUID 104 can be expressed as

$$I = Ic sin ( γ a ) + Ic sin ( γ b ) \qquad ( 1 )$$

γa and γb are phase jumps (phase difference) at the two Josephson junctions 102a and 102b, respectively,

$$γ b - γ a = 2 π ( Φ / Φ 0 ) \qquad ( 2 )$$

(Φ0 is the magnetic flux quantum, Φ0=h/(2e), his Planck's constant, and e is the elementary charge) Therefore, the magnetic flux Φ (external magnetic field) through the loop of the SQUID 104 can only be an integer multiple of the magnetic flux quantum Φ0.

$$Φ / Φ 0 = n ( n is a positive integer ) \qquad ( 3 )$$

The maximum value Imax of the current I flowing in SQUID 104 is given by

$$Imax = 2 I c \vert cos ( π Φ / Φ 0 ) \vert \qquad ( 4 )$$

As the magnetic flux Φ (external magnetic field) applied to the loop of the SQUID 104 is increased, the maximum current becomes 0 when Φ is (integer value+½)Φ0, and the magnetic flux quantum changes with the period of Φ0.

For example, if a magnetic field Φ smaller than ½ of the magnetic flux quantum Φ0 is applied through the loop of the SQUID 104 from bottom to top, a current flows through the loop of the SQUID 104 that generates a magnetic field in the direction that cancels the magnetic field (from top to bottom), and the magnetic field through the loop of the SQUID 104 is reduced to 0 (n=0 in Equation (3)). Alternatively, a current flows in the loop of the SQUID 104 in a direction that generates a magnetic field in the same direction as the field Φ, and the magnetic field through the loop of the SQUID 104 is Φ0 (n=1 in Equation (3)). In this case, generating a downward magnetic field in the loop of the SQUID 104 to set the magnetic flux Φ to 0 (n=0 in Equation (3)) is more energetically stable and the current value in the loop of the SQUID 104 is smaller as compared with generating an upward magnetic field to set the magnetic flux Φ to Φ0. A lower one of the two energy levels is called a ground state and the higher one of the two energy levels is called an excited state, for example. A two-level system consisting of the ground state and the first excited state can be treated as a qubit.

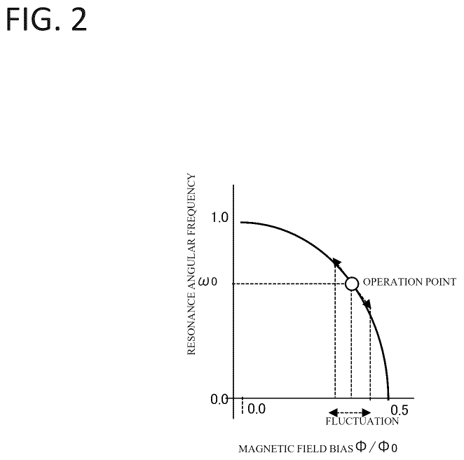

FIG. 2 is a graph showing a function of magnetic field dependence of a resonance angular frequency of the resonator 106 of the qubit 101 (Reference Literature 1). In the graph shown in FIG. 2, a horizontal axis is a magnetic field bias magnitude applied to a loop of the SQUID 104 (external magnetic flux Φ divided by the magnetic flux quantum Φ0: Φ/Φ0), and a vertical axis is a magnitude of a resonance angular frequency. Note that the vertical axis is normalized by a maximum value of a sonance angular frequency. When two Josephson junctions with equal critical current values are used, when an applied magnetic field Φ is Φ/Φ0=(2k+1)/2 (k is 0 or a positive integer), the critical current value of the entire loop of the SQUID 104 becomes 0 from Equation (4). When the critical current value on the entire loop of the SQUID 104 becomes zero, an equivalent inductance of the loop of the SQUID 104 becomes infinite, and the resonance angular frequency becomes zero. In the graph in FIG. 2, an operating point indicated by a circle indicates a resonance angular frequency set by a DC magnetic field (DC bias magnetic flux) generated by a DC current flowing through the inductor 111. As described above, in order to parametrically oscillate the resonator 106 of the qubit 101, in addition to a DC magnetic field (DC bias magnetic flux), an AC magnetic field (AC magnetic flux) is applied to the loop of the SQUID 104 by an AC current flowing through the inductor 111. In this case, a magnitude of a magnetic field applied to the loop of the SQUID 104 fluctuates periodically around a magnitude of the magnetic field generated by the DC current (operating point), and the resonance angular frequency of the resonator 106 also fluctuates.

It is known that an oscillation threshold of parametric oscillation (pump power threshold) is minimum when the frequency of the magnetic field is equal to twice the value of the resonance angular frequency (2000) and increases as an angular frequency of the AC magnetic field shifts from twice a value of the resonance angular frequency.

When the qubit 101 is set to an initial state (superposition of the ground state and the excited state), a signal output from the signal source 113 (e.g., a microwave with the resonance frequency of resonator 106) is supplied to a port 1 (p1) of the circulator 115 and output from a port 2 (p2) of the circulator 115, propagated through the input-output line 108, and is applied to the qubit 101 via a coupling capacitance 110.

A signal (microwave) may be input to the qubit 101 to read a state of the qubit 101. For example, the readout of the state of the qubit 101 may be performed using a reflected signal at qubit 101 of a signal input to the qubit 101 from the input-output line 108 via the coupling capacitance 110. In this case, a reflected signal (reflected wave) of a signal (signal wave) that propagates from the signal source 113 through the circulator 115 and the input-output line 108 and is supplied to the qubit 101 via the coupling capacitance 110, is supplied to the port 2 (p2) of the circulator 115, output from a port 3 (p3), and received by the measuring instrument 114 via an unshown coaxial line (cable), amplifier, or the like. Regarding reflection in a qubit, it has been known that the qubit 101 coupled to the input-output line 108, a one-dimensional coplanar waveguide, completely reflects a microwave signal on the waveguide at resonance frequency (e.g., a frequency corresponding to an energy difference between a ground state and a first excited state) (Reference Literature 2). The measuring instrument 114 may be, for example, a commercially available network analyzer or spectrum analyzer, etc. By measuring a reflected signal from qubit 101 with the measuring instrument 114, a state of the qubit 101 can be observed (read out).

FIG. 3A is a schematic plan view of a non-limiting example of a layout of the qubit 101 (part of a wiring layer of the quantum chip) in FIG. 1. The electrode 107 of the qubit 101 is a cross-shaped with four arms. The electrode 107 of the four arms is surrounded by a ground 120 (ground plane) via a gap 121. The gap 121, shown in white in the figure, corresponds to an area that is not covered by a wiring layer and may expose a surface of the substrate (e.g., silicon, etc.) of the quantum chip. The capacitance 105 in FIG. 1, placed in parallel to the SQUID 104 between the electrode 107 and the ground 120, corresponds to a capacitance of the gap 121 between the electrode 107 and the ground 120. A gap between an end of the input-output line 108 and an end of a first arm of the electrode 107 (the upward-facing arm in FIG. 3A) opposite the end of the input-output line 108 is the coupling capacitance 110 (capacitance component) of FIG. 1. Between an end of the second arm (right-facing arm in FIG. 3A) of the electrode 107 and the opposing ground 120 is provided a SQUID 104, which is inductively coupled to an inductor at one end of the control line 109 (SQUID 104 is smaller in size than others and is not shown in FIG. 3A.

FIG. 3B is a schematic plan view of an enlarged area near the SQUID 104 of the qubit 101 (area 11 surrounded by a square) in FIG. 3A. In the layout of FIG. 3B, the Josephson junctions 102a and 102b are also represented schematically with an X. Referring to FIG. 3B, the control line 109 is configured as a coplanar waveguide with both sides in the longitudinal direction sandwiched between grounds 120 (ground plane) via gaps 121a and 121b. In FIG. 3B, a center conductor (signal line) of the coplanar waveguide is indicated by a reference sign 109 representing the control line. One end of the control line 109 is contacted to the ground 120 (ground plane), and at the contact point the gap 121a of the coplanar waveguide is bent almost at a right angle. The wiring pattern of a linear shaped ground 120 (ground plane) bounded by the gap 121 and a gap 121c on the SQUID 104 side is shown by a reference sign 111, which represents an inductor. When a current from the control line 109 flows through this wiring pattern, a clockwise magnetic field is generated in accordance with Ampere's right hand screw rule, and acts as the inductor 111 to generate a magnetic flux that penetrates the loop of the SQUID 104. When the magnetic field (magnetic field lines) generated by the inductor 111 according to the right-hand screw rule reaches the ground 120 (ground plane), which is made of a superconducting member (Type 1 member), a superconducting current superconducting (eddy current) spontaneously flows inside the superconducting member at the ground 120 (ground plane) and a magnetic field (magnetic field flux) to the ground 120 (ground plane) is generated. Intrusion of a magnetic field (magnetic field lines) into the ground 120 (ground plane) is eliminated (Meissner effect). In the example shown schematically in FIG. 3B, a magnetic flux through the loop of the SQUID 104 is the magnetic flux generated by the inductor 111 with a current bent from one end of the control line 109 through the inductor 111 to ground 120. The magnetic flux penetrates a line shaped gap 121c from top to bottom of the paper, orbit through the substrate below the gap 121c, and penetrate the loop of the SQUID 104 from bottom to top of the paper. As shown in FIG. 3B, the SQUID 104 is located between the end of the arm of the electrode 107 and the ground 120 (ground plane) opposing the end of the arm of the electrode 107. The superconducting member 103a connected to one end of the Josephson junction 102a is connected to one end of the Josephson junction 102b via the electrode 107 made of superconducting material, and the superconducting member 103b are connected to the ground 120 (ground plane), forming the loop of the SQUID 104 in FIG. 1.

FIGS. 3A and 3B show an example of a planar circuit and Josephson junction layout formed by depositing superconducting materials on the substrate surface of a quantum chip, for example, by MBE (Molecular Beam Epitaxy), where silicon is used as the substrate. However, other electronic materials such as sapphire or compound semiconductor materials (Group IV, III-V, II-VI) may be used. The substrate should preferably be monocrystalline, but may also be polycrystalline or amorphous. As superconducting member materials, Nb (niobium) or Al (aluminum), for example, but not limited to, niobium nitride, indium (In), lead (Pb), tin (Sn), rhenium (Re), palladium (Pd), titanium (Ti), molybdenum (Mo), tantalum (Ta), tantalum nitrides, and alloys containing at least one of these, and any other metal that becomes superconducting when cooled to cryogenic temperatures may be used. A Josephson junction is a device with a tunnel junction structure in which a superconducting member such as Al and a superconducting member are sandwiched by a thin insulating film (e.g., AlOₓ), and is formed by, for example, a diagonal deposition method.

As described above, input-output line 108 and control line 109 are provided for each qubit 101. In this case, as the number of qubit 101 increases, wiring required increases, as a result, the so called wiring problem becomes a major issue. The above issue is one example and the present disclosure, though not limited to the above, can reduce the number of wirings of the qubit in various situations.

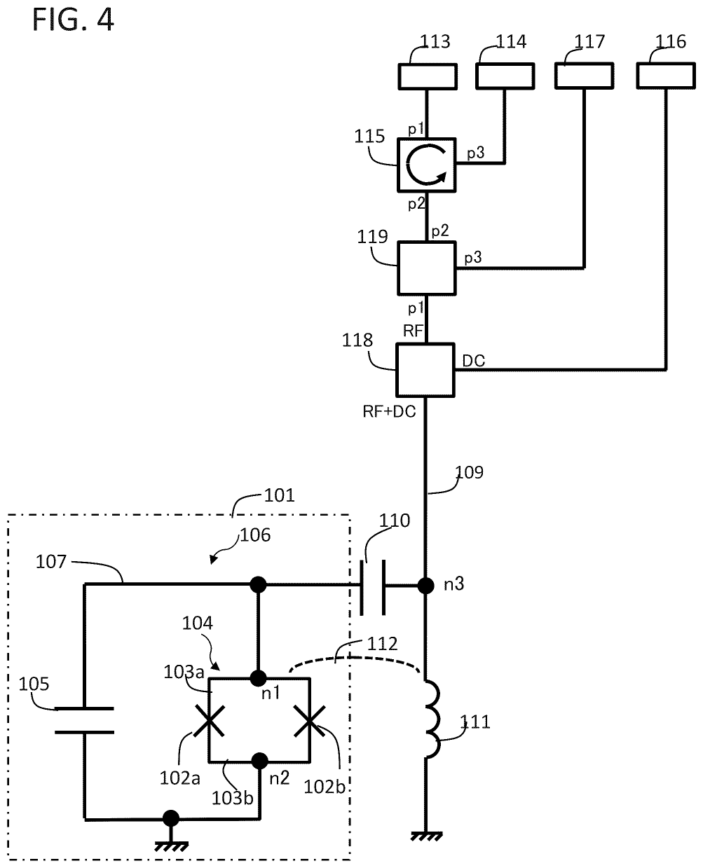

FIG. 4 illustrates schematically a configuration of an example qubit of example embodiments of the present disclosure. In FIG. 4, the same reference signs are, in principle, allotted to the same or equivalent elements as in FIG. 1, with descriptions thereof omitted a s appropriate to avoid redundancy, and differences are mainly described. In FIG. 4, the circuit configuration of the qubit 101 itself is the same as that in FIG. 1, and different from FIG. 1 in that the electrode 107 of the qubit 101 is connected to the control line 109 via the coupling capacitance 110. In FIG. 4, the control line 109 is the same as the reference sign in FIG. 1. In the example of FIG. 4, the input-output line 108 of FIG. 1 is deleted, and the control line 109 is connected to the inductor 111 to supply a signal (current) to generate a magnetic flux to be applied to the qubit 101. The control line 109 is configured to take on the function of an input-output line (108 in FIG. 1) that transmits a signal input to and/or output from the qubit 101 by a capacitive coupling.

The control line 109 has one end (node n3) connected to the electrode 107 of the resonator 106 via the coupling capacitance 110 and to one end of the inductor 111. The control line 109 has the other end connected to the bias T circuit 118 and connected to the DC power supply 116 and AC power supply 117 via the bias T circuit 118, as well as to the signal source 113 and the measuring instrument 114 via the circulator 115. In FIG. 4, a part of wiring of the control line 109 wiring (e.g., coplanar type line) may be used as the inductor 111. Of the control line 109 connecting to the ground 120, the control line 109 close to the SQUID 104 acts as the inductor 111. The wiring between the node n3 and the inductor 111 may be denoted as control line 109.

An AC signal (microwave) from the signal source 113 is transmitted by a coaxial cable or the like (not shown) arranged in a refrigerator (not shown), attenuated in steps by an attenuator (not shown) installed at each temperature stage, and supplied to the port 1 (p1) of the circulator 115. The signal supplied to the port 1 (p1) of the circulator 115 is transmitted in one direction, output from a port 2 (p2), supplied to the port 2 (p2) of the diplexer 119. When an AC signal from the AC power supply unit 117 is supplied to a port 3 (p3) of the diplexer 119, a signal combined with the AC signal is supplied from a port (p1) of the diplexer 119 to an RF port of bias T circuit 118. At an RF+DC port of the bias T circuit 118, when the DC signal from the DC power supply 116 is supplied to the DC port, the DC signal is superimposed with the AC signal from the RF port and applied to the control line 109 and is input via the coupling capacitance 110 to the qubit 101.

The output/reflected signal from qubit 101 is output to the control line 109 via the coupling capacitance 110 and is supplied to the port 2 (p2) of the circulator 115 via the bias T circuit 118 and the diplexer 119. The signal supplied to the port 2 (p2) of the circulator 115 is transmitted in one direction and output from the port 3 (p3), both of which are transmitted through an unshown low-pass filter, band-pass filter, isolator, HEMT amplifier, etc. to the measuring instrument 114 outside the refrigerator not shown.

An AC signal (microwave) from the AC power supply unit 117 is transmitted through a coaxial cable (not shown) arranged inside the refrigerator (not shown), and are attenuated in steps by attenuators (not shown) installed at each temperature stage, and are supplied to the port 3 (p3) of the diplexer 119, and DC signals from the DC power supply unit 116 are The DC signal from the DC power supply 116 is transmitted on a transmission line (not shown) or the like arranged inside the refrigerator and is supplied to the DC port of the bias T circuit 118 via a low-pass filter not shown.

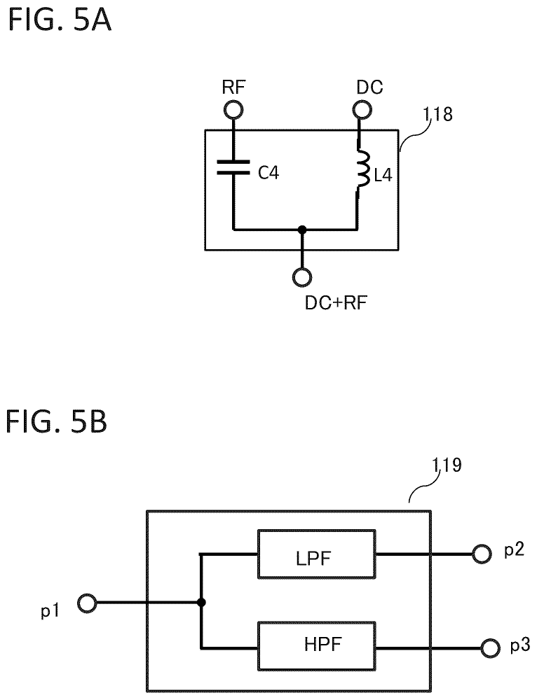

More specifically, in control of the qubit 101, the AC signal from the AC power supply unit 117 (frequency is about twice the resonance frequency of the qubit 101 (resonator 106)) is supplied to the port 3 (p3) of the diplexer 119, and the port 1 (p1) of the diplexer 119 outputs a signal that is a mixture of two signals supplied to the port 2 (p1) and the port 3 (p3). As schematically shown in FIG. 5B, the diplexer 119 has, for example, a low-pass filter (LPF) connected between the port 1 (p1) and the port 2 (p2) and a high-pass filter (HPF) connected between the port 1 (p1) and the port p3 (p3). In the diplexer 119, a directional coupler and filter or a circulator and filter may be used. It is assumed that no signal is output from the signal source 113 (no readout is performed) at this point of time. The port 1 (p1) of the diplexer 119 outputs an AC signal from the AC power supply 117, which is supplied to the RF port of the bias T circuit 118. From the RF+DC port of the bias T circuit 118, a signal in which the AC signal from the AC power supply 117 is superimposed on a DC current from the DC power supply 116 input to the DC port of the bias T circuit 118 is output to the control line 109. The node n3 of the control line 109 is connected to one end of the inductor 111 with the other end thereof connected to the ground 120. A current flowing in the inductor 111 generates a magnetic flux (DC flux+AC flux) applied to the loop of the SQUID 104 in the qubit 101.

Of the current flowing in control line 109, the DC current I_{DC} from the DC power supply 116 is blocked (cut) by the coupling capacitance 110, and the AC signal from the AC power supply 117 (frequency approximately twice the resonance frequency of the resonator 106) is supplied to the qubit 101.

Let the AC current component of the current flowing in the node n3 of the control line 109 be I(ω),
the AC current component of the current flowing from the node n3 of the control line 109 to the inductor 111 be I₁ (ω), and
the AC current component flowing from the node n3 of the control line 109 via the coupling capacitance 110 to the qubit 101 be I₂ (ω), where

$${I}_{2} ( ω ) = I ( ω ) - {I}_{1} ( ω ) ,$$

the circuit in FIG. 4 will be approximated using a simple model.

Let an inductance of the inductor 111 be L,
a value of coupling capacitance 110 be Cc, and
an impedance of the qubit 101 be Z_{q}(ω) (an angular frequency ω is approximately twice the resonance angular frequency of the qubit 101 (resonator 106) ω≈2ω0).

An impedance of a series circuit of Z_{q} (ω) and the coupling capacitance C_{c} is given by,

$$Z ( ω ) = {Z}_{q} ( ω ) + \frac{1}{i ω {C}_{c}} \qquad ( 5 )$$

At the node n3, the following holds.

$${I}_{1} ( ω ) \times i ω L = ( I ( ω ) - {I}_{1} ( ω ) ) \times \{ {Z}_{q} ( ω ) + \frac{1}{i ω {C}_{c}} \} \qquad ( 6 )$$

Therefore, I₁ (ω) and I₂ (ω) are given by

$${I}_{1} ( ω ) = I ( ω ) \frac{ω {Z}_{q} ( ω ) {C}_{c} - i}{ω {Z}_{q} ( ω ) {C}_{c} + i ( {ω}^{2} L {C}_{c} - 1 )} \qquad ( 7 )$$

$${I}_{2} ( ω ) = I ( ω ) - {I}_{1} ( ω ) = I ( ω ) \frac{i {ω}^{2} L {C}_{c}}{ω {Z}_{q} ( ω ) {C}_{c} + i ( {ω}^{2} L {C}_{c} - 1 )} \qquad ( 8 )$$

In Equations (7) and (8),
when an inductance of the electrode 107 of the qubit 101 is Le,
a value of the capacitance (shunt capacitance) 105 of the qubit 101 is C, an inductance of Josephson junctions 102a and 102b of the SQUID 104 are Ls1 (Φ) and Ls2 (Φ), respectively (where is a magnetic flux through the loop of the SQUID 104), critical current values of the Josephson junctions 102a and 102b are I_{c1} and I_{c2}, respectively, the impedance Z_{q}(ω) of the qubit 101 (series circuit of the resonator 106 (which includes the SQUID 104 and the capacitance 105) and the electrode 107) is given by

$${Z}_{q} ( ω ) = \frac{1}{\frac{{Ls}_{1} ( Φ ) + L {s}_{2} ( Φ )}{i ω ( {Ls}_{1} ( Φ ) \times L {s}_{2} ( Φ ) )} + i ω C} + i ω {L}_{e} \qquad ( 9 )$$

$$where$$

$$\begin{matrix}{Ls}_{i} ( Φ ) = \frac{{Φ}_{0}}{2 π {I}_{c i} cos ( \frac{2 π Φ}{{Φ}_{0}} )} & ( i = 1 , 2 )\end{matrix} \qquad ( 10 )$$

The current flowing from the node n3 of the control line 109 to the inductor 111 is a sum of the DC current I_{DC} and I₁ (ω).

The signal input to the qubit 101 via the coupling capacitance 110 of the current flowing through the node n3 of the control line 109 has an angular frequency of about twice the resonance angular frequency w0 of the qubit 101, a part of which is reflected in the resonator 106 of the qubit 101 (the remainder is transmitted through the resonator 106). The AC signal reflected by the qubit 101 (an AC signal with an angular frequency of approximately twice the resonant angular frequency ω0 of the qubit 101) returns to the control line 109 via the coupling capacitance 110 and is supplied to the RF+DC port of the bias T circuit 118. In the bias T circuit 118, the reflected signal (AC signal) input to the RF+DC port is output from the RF port via a capacitor between the RF+DC port and the RF port (C4 in FIG. 5A). In the bias T circuit 118, the reflected signal (AC signal) input from the RF+DC port is prevented (suppressed) from being output to the DC power supply 116 by the inductor (L4 in FIG. 5A) between the RF+DC port and the DC port.

The reflected signal output from the RF port of the bias T circuit 118 (an AC signal with an angular frequency of approximately twice the qubit's resonance angular frequency ω0) is supplied to the port 1 (p1) of the diplexer 119 and output from the port 3 (p3) of the diplexer 119. The reflected signal (an AC signal with an angular frequency of about twice the qubit's resonance angular frequency Φ0) supplied to the port 1 (p1) of the diplexer 119 is not output from the port 2 (p2) of the diplexer 119, and thus the port 2 (p2) of the circulator 115 does not propagate to the port 2 (p2) of the circulator 115. The reflected signal output from the port 3 (p3) of the diplexer 119 returns to the output end of AC power supply 117, but may be terminated (e.g., resistor series terminated) at the output end of the AC power supply 117.

In this state, when reading out a state of the qubit 101, the signal source 113 outputs an AC signal (microwave signal with a frequency set to a resonance angular frequency ω0 of the qubit 101). The AC signal from the signal source 113 is supplied to the port 1 (p1) of the circulator 115, output from the port 2 (p2) of the circulator 115, and supplied to the port 2 (p2) of the diplexer 119. An AC signal (with an angular frequency of about twice the resonance angular frequency ω0 of the qubit 101) from the AC power supply unit 117 is supplied to the port 3 (p3) of the diplexer 119. The signal into which the two signals supplied to the port 2 (p2) and the port 3 (p3) of the diplexer 119, are combined is output from the port 1 (p1) of the diplexer 119 and is supplied to the RF port of the bias T circuit 118. The DC current from the DC power supply 116 is supplied to the DC port of the bias T circuit 118. From the RF+DC port of the bias T circuit 118, the DC current from the DC power supply 116 superimposed with a signal into which the AC signal (microwave) from the signal source 113 and the AC signal from the AC power supply 117 are combined is output to the control line 109.

In the qubit 101, the combined signal of the AC signal (microwave) from the signal source 113+the AC signal (microwave) from the AC power supply device 117 is input from the node n3 of the control line 109 via the coupling capacitance 110. In this case, the sum current of a part I′₂(ω0) of the AC signal I′(ω0) from the signal source 113 and a part I″₂(2×ω0) of the AC signal I″₂(2×ω0) from the AC power supply unit 117, I′₂ (ω0)+I″₂(2×ω0), flowing in the control line 109, is supplied to the qubit 101 via the coupling capacitance 110. Here, I′₂(ω0) and I″₂(2×ω0) are obtained from equation (8), respectively.

It is assumed that qubit 101 is configured to be able to oscillate at an angular frequency of ω0, and a part or almost all of the AC signal with an angular frequency of ω0 input to the qubit 101, shall be reflected. The AC signal with an angular frequency of 2×ω0 is supplied to the qubit 101, and a part of the signal is reflected. The signal reflected by the qubit 101 (a superposition of the AC signal with an angular frequency of ω0 and the AC signal with an angular frequency of 2×ω0) returns to the control line 109 via the coupling capacitance 110 and is supplied to the RF+DC port of the bias T circuit 118. In the bias T circuit 118, the reflected signal (the combined signal of the AC signal with an angular frequency of ω0 and the AC signal with an angular frequency of about 2×ω0) is supplied to the RF+DC port and output from the RF port of the bias T circuit 118 via the capacitor (C4 in FIG. 5A) between the RF+DC port and the RF port. The reflected signal output from the RF port of the bias T circuit 118 is supplied to the port 1 (p1) of the diplexer 119. Of the reflected signal supplied to the port 1 (p1) of the diplexer 119, the reflected signal (with an angular frequency of ω0) for the signal output from the signal source 113 passes through the low-pass filter (LPF) of the diplexer 119 and is output to the port 2 (p2) of the diplexer 119. The reflected signal output from the port 2 (p2) of the diplexer 119 is supplied to the port 2 (p2) of the circulator 115, propagates in one direction to the port 3 (p3) of the circulator 115, is output from the port 3 (p3) thereof, and is transmitted to the measuring instrument 114. The reflected signal (AC signal with angular frequency ω0) from qubit 101 can be measured by the measuring instrument 114 to read out a state of the qubit 101. An input connector of the measurement instrument 114 may be terminated with, for example, a 50 Ohm termination to suppress further reflection on the measuring instrument 114 side of the reflected signal that has reached the measuring instrument 114. The AC signal (microwave) output from the signal source 113 may be a contiguous wave (CW) or a pulse wave. When the AC signal (microwave) output from the signal source 113 is a pulse wave, an output period should be such that the input signal (pulse wave) to the control line 109 and the reflected signal (pulse wave) from the control line 109 to the measurement device 114 do not collide in timing at the port 2 of the circulator 115.

With respect to the signal supplied to the port 1 (p1) of the diplexer 119, the reflected signal reflected at the qubit 101 (reflected AC signal with an angular frequency of approximately 2×Φ0) for the signal output from the AC power supply 117 passes through the high pass filter (HPF) of the diplexer 119 and is output from the port 3 (p3) of the diplexer 119, back to the output end of the AC power supply unit 117. In this case, the output end of the AC power supply unit 117 may be subjected to resister series termination.

The DC current IDC from the DC power supply 116, the AC signal I″₁(2×ω0) from the AC power supply 117 (angular frequency=about twice the qubit 101 resonance angular frequency Φ0: given by Equation (7) from I″(2×ω0)) and the signal source 113 (angular frequency=resonance angular frequency of the qubit 101 ω0: given by Equation (7) from I′(ω0)) from the signal source 113 are combined (sum current) I_{DC}+I′₁(ω0)+I″₁(2×ω0) flows from the node n3 to the inductor 111. The signal (microwave) from the signal source 113 is about one-half the frequency of the AC signal from the AC power supply 117 and has a very low power, so an effect of the signal from the signal source 113 on a magnetic flux generated by the inductor 111 (the magnetic flux Φ through the SQUID 104) is negligible. A magnetic field H generated by the inductor 111 with the right-hand thread law is proportional to the current I₁ (ω) flowing through the inductor 111, and the magnetic flux Φ is Φ=BS=μHS (B is a magnetic flux density, μ is a magnetic permeability, S is an area of the loop in the SQUID 104). The AC signal from the signal source 113 has a weak power compared to the DC current I_{DC} from the DC power supply 116, and its frequency is about half of the frequency from the AC power supply 117, which is significantly different, and thus an effect of the AC signal from the signal source 113 on a magnetic flux penetrating the loop of the SQUID 104, i.e., an effect thereof on parametric oscillation of SQUID 104 is negligible.

Readout of the qubit 101 may be performed within a decoherence time (a time during which a quantum mechanical superposition state remains stable) of the qubit 101 after the signal supply to the control line 109 (inductor 111) is stopped. In this case, the AC signal (microwave) from the signal source 113 propagates through the circulator 115, diplexer 119, bias T circuit 118, and control line 109, with a part of the AC signal branching into the inductor 111 and other part supplied via the coupling capacitance 110 to the qubit 101. The signal (microwave) reflected by qubit 101 travels in the opposite direction back to the control line 109 via the coupling capacitance 110, propagates through the bias T circuit 118, diplexer 119, and circulator 115, and then reaches the measuring instrument 114.

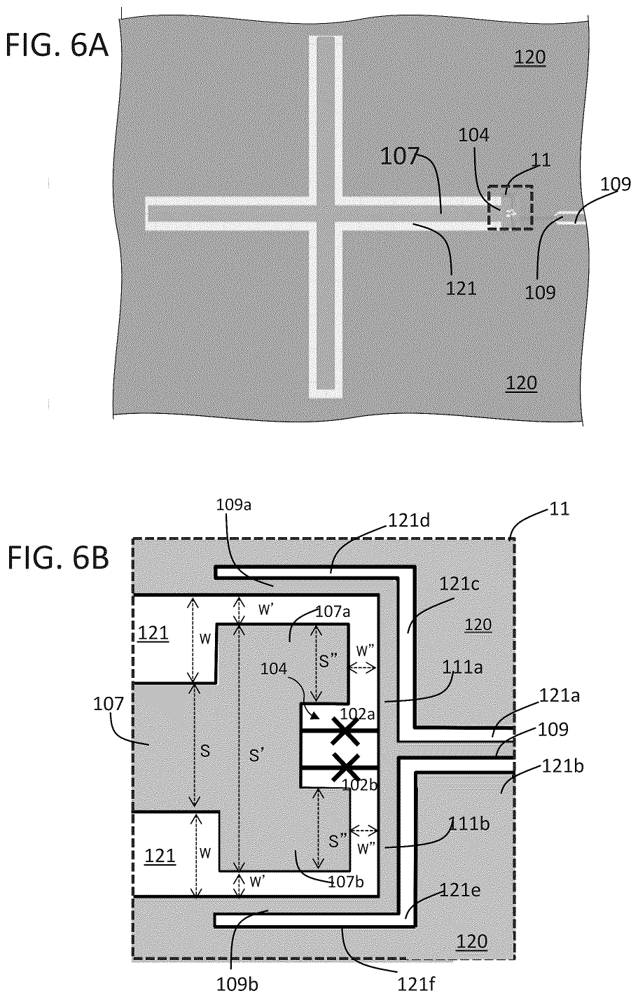

FIG. 6A shows an example layout of the qubit 101 in FIG. 4. Referring to FIG. 6A, the control line 109 inductively and capacitively coupled at different points to the qubit 101. The input-output line 108 shown in FIG. 3A is not provided. The gap 121 shown in white between the electrode 107 of the qubit 101 and the ground 120 (ground plane) opposite an edge of the electrode 107 constitutes the capacitance 105 in FIG. 4.

FIG. 6B schematically shows an enlarged view of the region 11 close to the SQUID 104 in the qubit 101 of FIG. 6A. FIG. 6B schematically shows an example of a layout pattern in which the coupling capacitance 110 is set to an appropriate value so that an external Q-value of the resonator 106 takes a desired value. A Q-value (Q-factor) of the resonator represents sharpness of the resonance and is given by Q=ω0/Bw, where Bw is a frequency range such that a power consumed in the resonator 106 is ½ of a peak power value, relative to a frequency (resonance angular frequency) ω0 at which the power stored in the resonator. An external Q-value is given by a ratio of an energy stored in the resonator to an energy flowing out of the resonator to the external circuit (load resistance or internal resistance of the power supply) in one cycle. The larger the external Q-value, the weaker coupling to the external circuit, while the smaller, the stronger the coupling. The Q-value of the resonator (load Q-value) is given by an internal Q value Qi and the external Q value Qe, as

$$1 / Q = 1 / Qi + 1 / Qe \qquad ( 11 )$$

In FIG. 6B, to make the coupling capacitance 110 value large to a desired degree, the electrode 107 of the qubit 101 is placed closer to the opposing control line 109 with a wider tip. For example, in FIG. 3B, the electrode 107 of the qubit 101 has a constant width S to the tip, but the electrode 107 of the qubit 101 in FIG. 6B is wider at its tip (the portion of the electrode 107 opposite the inductor). In addition, the wirings that are extended in opposite directions to each other at a predetermined distance from the tip of the electrode 107 by bifurcating one end of the control line 109 at a right angle, act as inductors 111a and 111b, and are also bent by 90 degrees and extended along the side of the electrode 107. A gap 121 between control lines 109a and 109b and the electrode 107 can be said to form the coupling capacitance 110.

More specifically, in a cross-shaped electrode 107 with arms extending from a center in four directions, in FIG. 6B, one arm of the electrode 107 (in FIG. 6A, the arm extending to the right side of the figure) is extended (elongated) with a center conductor width S and slot widths on both sides W. At a leading edge of the arm, the center conductor width is widened to S′ and the slot widths on both sides are reduced to W′.

$${S}^{′} + 2 {W}^{′} = S + 2 W \qquad ( 12 )$$

$${S}^{′} > S , {W}^{′} < W \qquad ( 13 )$$

Furthermore, on the tip side of the arm of the electrode 107, the electrode tips 107a and 107b with a center conductor width of S″ (S″<S′/2) are protruded in two halves. The Josephson junctions 102a and 102b of the SQUID 104 are bridged between a recess between the electrode tips 107a and 107b (width S′-2S″) and the wiring opposed thereto (also inductors 111a and 111b).

The width W′ of the gap between the edge (upper edge) of the electrode tip 107a and the control line 109a opposed thereto, the width W′ of the gap between the edge (lower edge) of the electrode tip 107b and the control line 109b opposite opposed thereto is narrower than the width W of the gap between the electrode 107 and the ground 120 except for the electrode tips 107a and 107b. A width W″ of the gap between the ends of electrode tips 107a and 107b and the inductors 111a and 111b opposed thereto is smaller than the gap between the electrode 107 and the inductor 111 in FIG. 3B. W″ may be equal to the gap W′ between the electrode tips 107a, 107b and the opposing control lines 109a, 109b. The capacitance between the electrode tips 107a, 107b and the control lines 109a, 109b opposed thereto (coupling capacitance 110 in FIG. 4) is larger as a length of sides opposite each other of the electrode tips 107a, 107b and the control lines 109a, 109b increases and a width of the gap between the sides opposite each other decreases. Let a spacing (distance) between opposite sides of parallel conductors d and the length between opposite sides 1, the electrostatic capacitance C is given by ε(1/d), where ε is the dielectric constant.

As shown in FIG. 6B, one end of the control line 109 is extended with two branches to form inductors 111a and 111b, facing the SQUID 104 between the electrode tips 107a and 107b, respectively, and then bent at right angles to form control line 109a, 109b extended along edges of the electrode tips 107a and 107b, thereby forming a long region with a narrow gap between the electrode 107 (electrode tips 107a, 107b) and control line 109 of the qubit 101, and the coupling capacitance 110 (not shown) of a sufficiently large value (capacitance value) is formed between the electrode 107 (electrode tips 107a and 107b) and the control line 109. However, if the coupling capacitance 110 value becomes too large, the external Q value of the qubit 101 becomes too low. Therefore, the coupling capacitance 110 may be set to an appropriate value using electromagnetic field simulation or the like.

The external Q value Qe of the resonator is larger when a coupling with a load, an internal resistance of the power supply, etc. is weak, and smaller when the coupling is strong. When the coupling between the control line 109 and the resonator 106 of the qubit 101 is too weak, it becomes difficult to read out a state of the qubit 101. When the coupling between control line 109 and the resonator 106 of the qubit 101 is too strong, a Q value of the resonator 106 decreases. For example, when the resonance frequency of the resonator 106 is set near its maximum value, the external Q value of the 30 signal input from control line 109 to the qubit 101 might be between 10,000 and 100,000. The external Q value may preferably be between 10,000 and 50,000. It may be further preferred that the external Q value be between 10,000 and 30,000.

Referring to FIG. 6B, according to electromagnetic simulations, the external Q value is about 23,000, which is in a preferred range. The internal and external Q values of the qubit 101 can be measured experimentally, for example, as follows. First, a reflection coefficient (ratio of reflected wave to incident wave) is measured with the measuring instrument 114 when a signal is supplied to the qubit 101 from the signal source 113. A reflection coefficient Γ is also called S parameter S11. The reflection coefficient Γ is measured by the measuring instrument 114 by frequency sweeping the signal input to the qubit 101 from the signal source 113. A frequency range of this measurement may be set to include the resonance angular frequency ω0 of the resonator 106 of the qubit 101. This measurement of the reflection coefficient (S11) can be performed using a vector network analyzer, for example. A vector network analyzer is a device in which the signal source 113 and the measurement instrument 114 are implemented in a single housing. By fitting a theoretical equation to the frequency dependence of the reflection coefficient obtained from this measurement, the internal and external Q values of the qubit 101 may be calculated.

In FIG. 6B, when a signal in which an AC signal (frequency about twice the resonance angular frequency of the resonator 106) from the AC power supply unit 117 is superimposed on a DC current from the DC power supply unit 116 is propagated through the control line 109, the superimposed signal (current) I flows through the control line 109, which is split into two wires (inductors 111a and 111b) with a current value of I/2, and applied to the electrode 107 of the qubit 101 by capacitive coupling from the control lines 109a and 109b, respectively. The electrode tips 107a and 107b, inductors 111a and 111b, and control lines 109a and 109b are configured to be line symmetrical about the central axis of the control line 109 and SQUID 104.

During readout of the qubit 101, the DC current from the DC power supply 116 is superimposed on the AC signal (frequency approximately twice the resonance frequency of the resonator 106) from the AC power supply 117 and the AC signal (frequency equivalent to the resonance frequency of the resonator 106) from the signal source 103. When the superimposed signal (current) I′ flows through the control line 109, the superimposed signal (current) I′ is split into a current value I′/2 by the wiring (inductors 111a and 111b) where the control line 109 is split into two wires (inductors 111a and 111b), and flows through the coupling capacitor I′/2. The AC current is supplied to the electrode 107 through the coupling capacitor (composed of the electrode tips 107a, 107b and the opposite sides of the inductors 111a, 111b and the gap 121 therebetween).

As described above, the number of wires to be coupled to the qubit is reduced by half, from two input-output lines and one control line to one control line. This makes it possible to suppress increase in the number of wires accompanied with increase in the number of qubits.

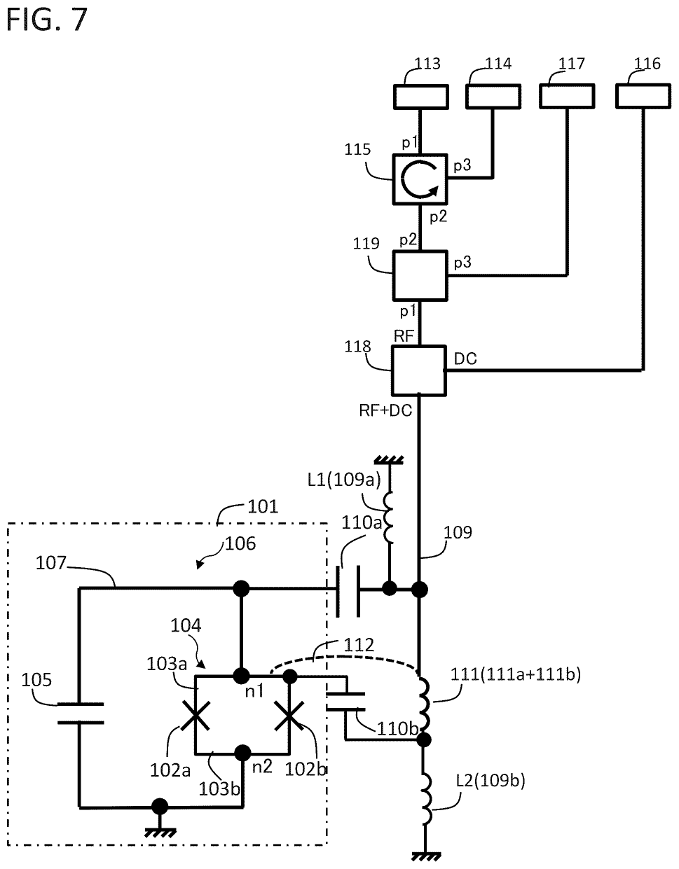

In FIG. 6B, the inductors 111a and 111b may be regarded as part of the wiring that constitutes the control line 109. The control lines 109a and 109b opposed to edges of the electrode tips 107a and 107b may be regarded as opposite electrodes on the control line 109 side, as well as wirings between the inductors 111a and 111b to supply a magnetic flux to the SQUID 104 and ground, or as a part of the inductors 111a and 111b. In this case, FIG. 6B can be represented as a circuit, for example, as shown in FIG. 7. FIG. 7 illustrates the layout of FIG. 6B as a circuit configuration. The electrode 107 of the qubit 101 and the node n1 of the SQUID 104 are coupled with the control line 109 (109a, 109b in FIG. 6B) via coupling capacitance 110a and 110b. The inductor 111 in FIG. 7 is connected to the control lines 109a and 109b. The control lines 109a and 109b, which have one ends connected to ground (120 in FIG. 6B), when current flows therethrough, generate a magnetic flux and also act as inductors L1 and L2.

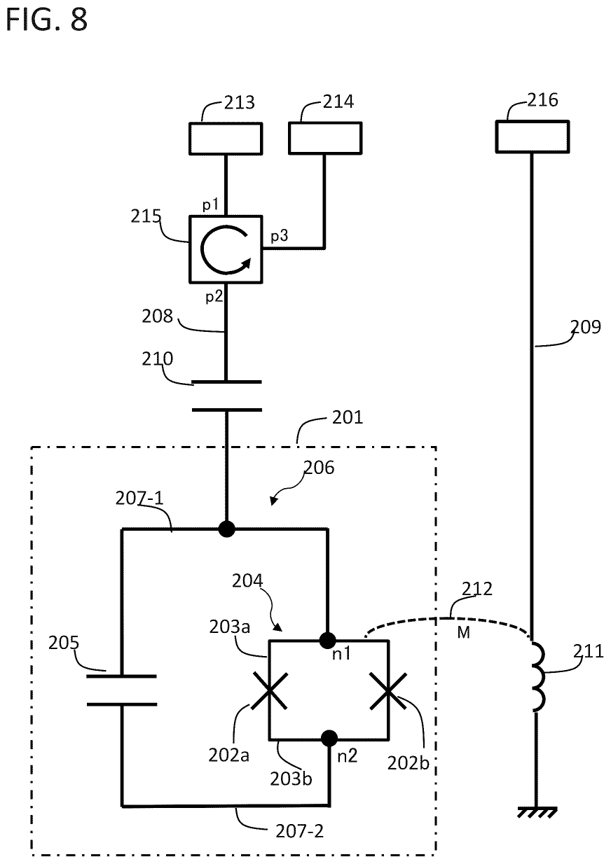

FIG. 8 illustrates a comparative example of a frequency-variable coupler. The frequency-variable coupler 201 has a SQUID 204 with two Josephson junctions 202a and 202b connected in a loop by superconducting members 203a and 203b. The two Josephson junctions 202a and 202b are connected in parallel in two paths between one end (node n1) and the other end (node n2) of the SQUID 204. The one end (node n1) of the SQUID 204 is connected to the first electrode 207-1 and the other end (node n2) is connected to the second electrode 207-2. A capacitance 205 is connected between the first electrode 207-1 and the second electrode 207-2. In FIG. 8, the configuration of the SQUID 204 is shown with two Josephson junctions, but the number of Josephson junctions in the loop of the SQUID may be arbitrary.

An input-output line 208 and a control line 209 are coupled to the coupler 201. The control line 209 corresponds to the control line 109 in FIG. 1 and supplies current to an inductor 211. The input-output line 208 may be used for initial setting of the coupler 201 and reading out a status of the coupler 201. One end of the input-output line 208 is connected to the coupling capacitance 210 during operation of the coupler 201. The other end of the input-output line 208 is connected to a signal source 213 and a measuring instrument 214 via a circulator 215. A magnetic flux bias line 209 is connected to a DC power supply 216. When the coupler 201 is operating, an inductor 211 connected to one end of the magnetic flux bias line 209 is electromagnetically coupled to the coupler 201 via a mutual inductance 212. The magnetic flux bias line 209 is connected to ground via an inductor 211. A DC current flowing in the magnetic flux bias line 209 generates a DC magnetic field. By varying the DC current value, the magnetic flux through the SQUID 204 of the coupler 201 is varied, and a resonance frequency ωᵣ (operating point) of the coupler 201 is controlled variably. The magnetic flux bias line 209 is connected to a DC power supply unit 216.

The coupler 201 is placed in a refrigerator not shown and cooled to an extremely low temperature (cryogenic temperature). The signal source 213, measuring instrument 214, and DC power supply 216 are located outside the refrigerator (not shown) in a room temperature environment. During operation of the coupler 201, a signal from the signal source 213 outside the refrigerator (not shown) is transmitted by a coaxial cable(s), etc. arranged inside the refrigerator, attenuated in steps by attenuators (not shown) installed at each temperature stage, transmitted to the input-output line 208 via circulator 215, and supplied to the coupler 201. An output signal from the coupler 201/reflected signal of the input signal is transmitted from the input-output line 208 through a circulator 215 to the measuring instrument 214 outside the refrigerator via unshown low-pass filter and/or band-pass filter, isolator, HEMT amplifier, etc. The DC current from the DC power supply unit 216 is transmitted by a transmission line(s), etc. arranged inside the refrigerator, supplied to the magnetic flux bias line 209 via an unshown low-pass filter, and flows to ground via an inductor 211.

During operation of the coupler 201, a signal from the signal source 213 are supplied to the port 1 of the circulator 215 and output from the port 2 thereof, passing through the input-output line 208 and through the coupling capacitance 210 to the first electrode 207-1. A reflected signal from the coupler 201 propagates through the input-output line 208 via the coupling capacitance 210, is supplied to the port 2 of the circulator 215, output from the port 3 of the circulator 215 and supplied to the unshown receiving circuitry of the measuring instrument 214.

By measuring the output signal from the coupler 201/reflected signal of the input signal with the measuring instrument 214, a resonance frequency, etc. of the coupler 201 can be measured. A DC current from the DC power supply unit 216 flows through the magnetic flux bias line 209, through the inductor 211 to the ground 120, and a DC magnetic field is applied via the mutual inductance 212, through the loop of the SQUID 204. A resonance frequency of the resonator 206 of the coupler 201 varies depending on a value of the magnetic flux penetrating the SQUID 204. By changing a value of the DC current output from the DC power supply unit 216 as shown in FIG. 2, the value of the magnetic flux penetrating the SQUID 204 can be changed, and the resonance frequency of the resonator 206, or resonance frequency of the coupler 201 (operating point) of the coupler 201, can be changed.

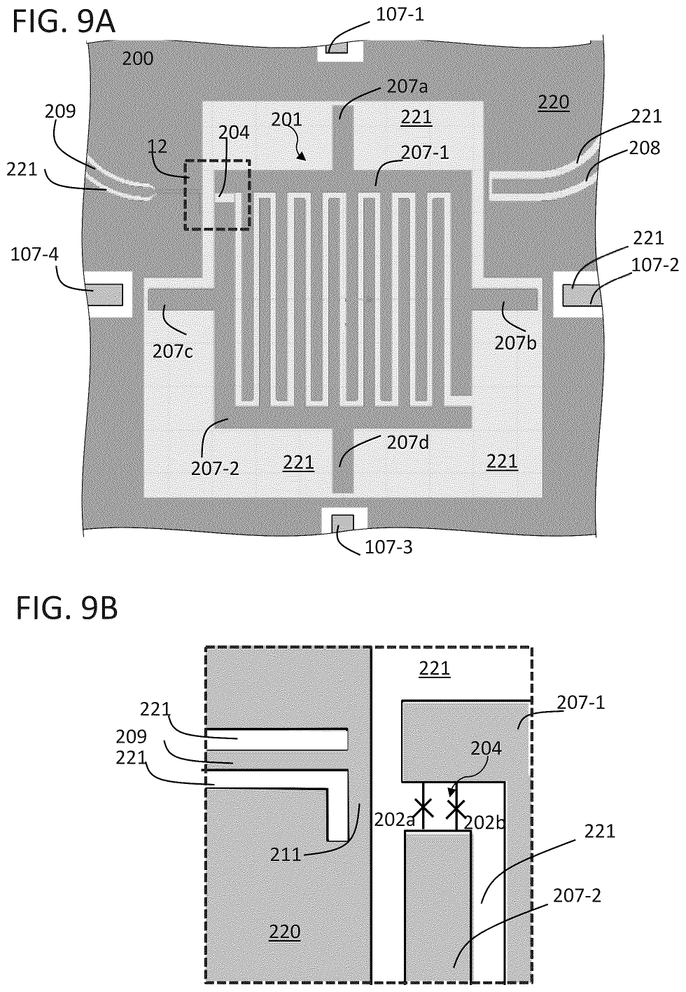

FIG. 9A schematically illustrates a non-limiting example of a layout of a coupler 201. The coupler 201 has a first electrode 207-1 of an inverted L-shape with a horizontal side and a vertical side, a second electrode 207-2 of an inverted L-shape with a horizontal side and a vertical side disposed opposed to the horizontal and vertical sides of the first electrode 207-1, wherein the first electrode 207-1 and the second electrode 207-2 each have nested projections (fingers) to each other from one lateral side to the other and have a comb-like nested structure (interdigital type capacitor structure). In the non-limiting example of FIG. 9A, in the nested structure electrode, each of the opposing finger pairs is a parallel plate capacitor, and 13 pairs of parallel plate capacitors are connected in parallel. The Josephson junctions 202a and 202b of the SQUID 204 are connected between one end of the horizontal side of the first electrode 207-1 (left end of the figure) and one end of the vertical side of the second electrode 207-2 (top end of the figure). At the center of the horizontal and vertical sides of the first electrode 207-1, there are provided protrusions 207a and 207b are provided with tips capacitively coupled to tips of the arms of the cross-shaped electrodes 107-1 and 107-2 of the first and second qubits, respectively. In the center of the vertical side and the center of the horizontal side of the second electrode 207-2, there are provided protrusions 207a and 207b with tips capacitively coupled with tips of the arms of the third and fourth qubit cross-shaped electrodes 107-3 and 107-4, respectively. In this example, the coupler 204 couples the first through fourth qubits by four-body interaction. The magnetic flux bias line 209 and input-output line 208 may be configured as coplanar waveguides with ground 220 arranged via gaps 221 on both sides.

FIG. 9B shows an enlarged schematic layout of the region 12 including SQUID 204 in FIG. 9A. The magnetic flux bias line 209 is configured as a coplanar waveguide surrounded by a ground 220 via a gap 221 on both sides in the longitudinal direction. An end of the magnetic flux bias line 209 is bent at a right angle, and a center conductor of the magnetic flux bias line 209 bent forms an inductor 211 connected to ground 220 at one end. A DC current fed to the magnetic flux bias line 209 flows from the inductor 211 to ground 22.

As described above, the input-output line 208 for reading a status of the coupler 201 and the magnetic flux bias line 209 for adjusting the resonance frequency of the coupler 201 are provided for each coupler 201. As the number of couplers 201 increases, wiring becomes an issue when they are integrated. In particular, the coupler 201 with four-body interaction is surrounded by the four nearest qubits 101, making it difficult to route the input-output line 208 and the magnetic flux bias line 209 on a planar circuit, and thus three-dimensional wiring is required, for example. The above issue is one example. The present disclosure, which is not limited to solve the above issue, can reduce the number of wirings of the coupler 201 in various situations.

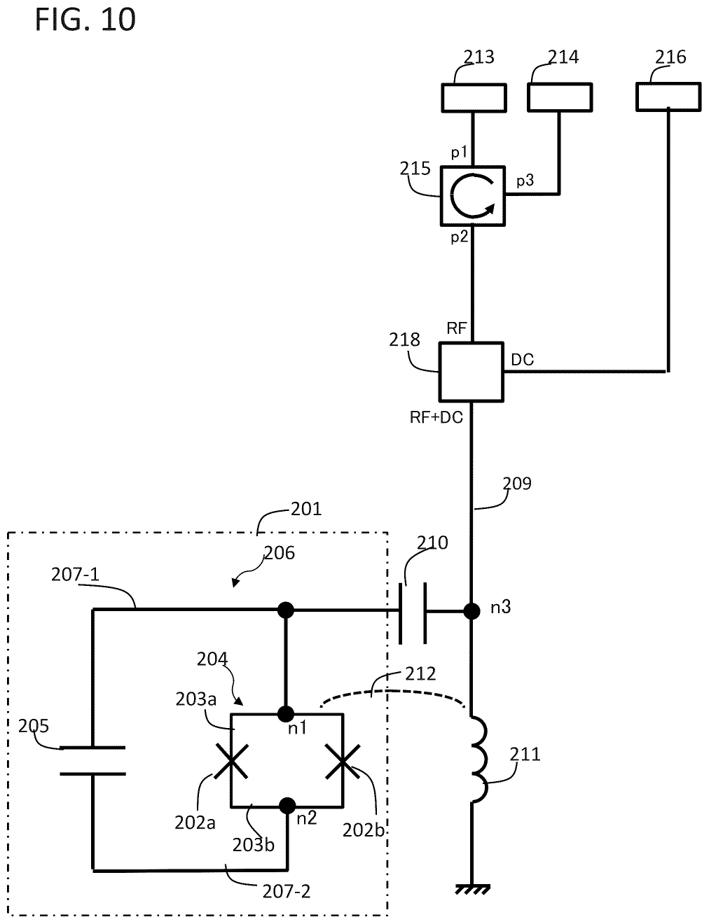

FIG. 10 illustrates an example of the coupler 201 of the present disclosure. In the configuration of FIG. 10, the same or equivalent elements as in FIG. 8 are marked with the same or equivalent reference signs, and their descriptions are omitted as appropriate to avoid duplication. The SQUID 204 is identical to that in FIG. 8, with a difference that the first electrode 207-1 is connected to the magnetic flux bias line 209 via the coupling capacitance 210. That is, the input-output line 208 in FIG. 10 is deleted, and one magnetic flux bias line 209 is configured to have functions of both the input-output line 208 in FIG. 8 and the magnetic flux bias line 209 to conduct a DC current to the inductor 211. The magnetic flux bias line 209 is connected not only to the DC power supply 216, but also to the signal source 213 and the measurement instrument 214 through the circulator 215.

When the coupler 201 is set to an initial state (superposition of the ground state and the excited state), an AC signal output from the signal source 213 (e.g., a microwave signal with a frequency set to the resonance frequency of the resonator 206) is supplied to the port 1 (p1) of the circulator 215, output from the port 2 (p2) thereof and propagates through the bias T circuit 218 to the magnetic flux bias line 209 and is applied to the coupler 201 via the coupling capacitance 210.

The following describes a control operation of the coupler 201. At this point of time, no signal may be output from the signal source 213 (no readout being performed). A DC current from the DC power supply 216 is supplied to the DC port of the bias T circuit 218. A DC current output from the RF+DC port of the bias T circuit 218 is supplied to the magnetic flux bias line 209 and flown to the inductor 211, generating a magnetic flux penetrating the SQUID 204 of the coupler 210 to determine an operating point of the resonance frequency of the coupler. The node n3 of the magnetic flux bias line 209 is connected via the coupling capacitance 210 to the first electrode 207-1 of the resonator 206. The DC current from the DC power supply 216 is not flown to the coupler 210 side.

The following describes an operation of reading out a state of the coupler 201. A state of the qubit may be read out by applying a signal (microwave) to the coupler 201 to change a state of the qubit and then reading out the state of the qubit. In this case, a reflected signal of the input signal to the coupler 201 may be used to read out the state of the coupler 201. The reflection at the resonator 206 of the coupler 201 changes a superposition state of the ground and excited states in the coupler 201. An AC signal (microwave signal with an angular frequency set to the resonance frequency of the resonator 206 of the coupler 201) output from the signal source 213 is supplied to the port 1 (p1) of the circulator 215 and output from the port 2 (p2) thereof and supplied to the RF port of the bias T circuit 218. It is supplied to the RF port of the bias T circuit 218. A DC current from the DC power supply unit 216 is supplied to the DC port of the bias T circuit 218, and the signal from the signal source 213 superimposed on the DC current from the DC power supply unit 216 is output from the RF+DC port of the bias T circuit 218 and supplied to the magnetic flux bias line 209. The node 3 of the magnetic flux bias line 209 is connected to one end of the coupling capacitance 210, the other end of which is connected to the first electrode 207-1, and to one end of the inductor 211, the other end of which is connected to ground.

An AC signal from the signal source 213 is applied from the node n3 of the magnetic flux bias line 209 to the electrode 207-1 of the coupler 201 via the coupling capacitance 210. The superimposed DC current from the DC power supply 216 and the current (microwave signal) output from the signal source 213 flows to ground through the inductor 211 to generate a magnetic field that penetrates the loop of the SQUID 204. The DC current from the DC power supply 216 determines the operating point (resonance frequency ωᵣ) of the resonator 206 of the coupler 201. The AC current output from the signal source 213 is weak in power compared to the DC current from the DC power supply unit 216. The DC current from the DC power supply unit 216 determines an operating point (resonance frequency) of the resonator 206 of the coupler 201. Therefore, an effect (fluctuation) of the AC current output from the signal source 213 on the operating point (resonance point) of the resonator 206 of the coupler 201 can be ignored.

The reflected signal of the signal supplied to the coupler 201 propagates back to the magnetic flux bias line 209 via the coupling capacitance 210 and is supplied to the RF+DC port of the bias T circuit 218. In the bias T circuit 218, the reflected signal (AC signal) supplied to the RF+DC port is output to the RF port via a capacitor between the RF+DC port and the RF port. The reflected signal output from the bias T circuit 218 is supplied to the port 2 (p2) of the circulator 215 and propagates from the port 3 (p3) of the circulator 215 to the measuring instrument 214. The measuring instrument 214 measures the reflected signal from the resonator 206 of the coupler 201 to read out the state of the coupler 201.

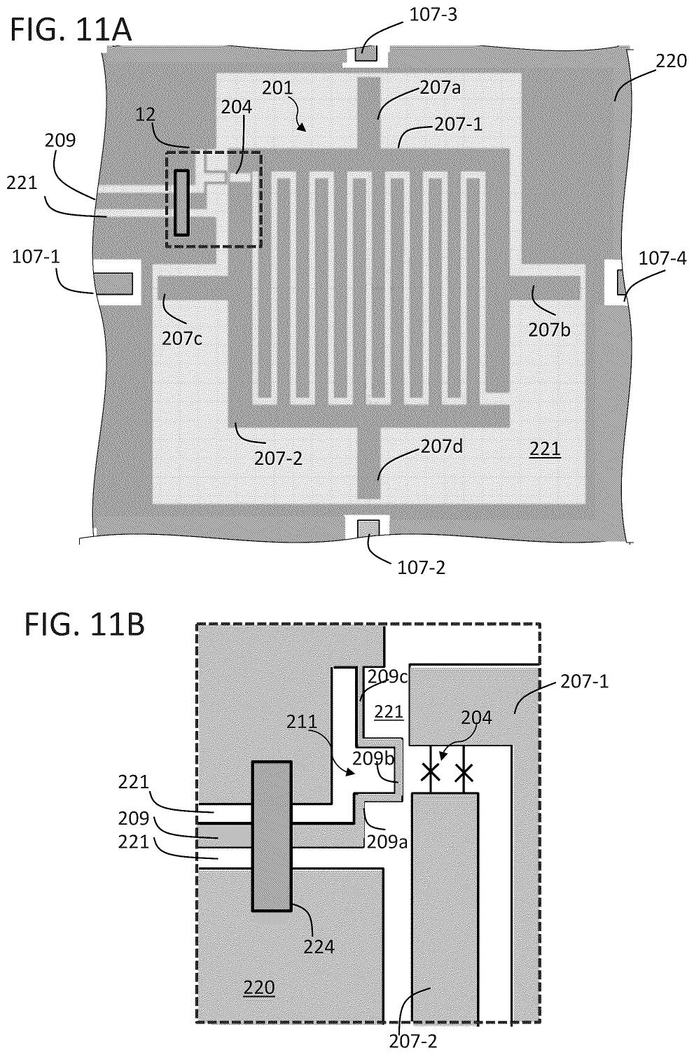

FIGS. 11A and 11B show a non-limiting example of the layout of the coupler 201 of FIG. 10. FIG. 11B is a schematically enlarged partial view of the area 12 in FIG. 11A. As shown in FIG. 11B, widening of a width of the magnetic flux bias line 209 brings out formation of the capacitance 210 of sufficiently large value between an end face of the tip of the magnetic flux bias line 209 and the first electrode 207-1 of the coupler 201 (FIG. 10). Furthermore, the inductor 211 connected to the tip of the magnetic flux bias line 209 is placed close to the SQUID 204 to ensure a mutual inductance 212 (FIG. 10) of sufficient magnitude.

As shown in FIG. 11B, the tip of the magnetic flux bias line 209 is shaped in an abbreviated U-shape and is placed close to the SQUID 204 that bridges electrodes 207-1 and 207-2. In order to make the coupling capacitance 210 large to a desired degree, the tip of the magnetic flux bias line 209 is shaped in an inverted U-shape and the length of the side opposite the electrode 207 is made large. The wider the magnetic flux bias line 209 is, the larger the coupling capacitance 210 between the magnetic flux bias line 209 and the first electrode 207-1 can be made. However, if the coupling capacitance 210 should be too large, the external Q value of the coupler 201 would be low. Therefore, the coupling capacitance 210 is set to an appropriate value.

More specifically, at one end of the magnetic flux bias line 209 (center conductor), a line-shaped conductor pattern 209a (superconducting conductor pattern) bent and extended at a right angle to be parallel to the second electrode 207-2, a conductor pattern 209b (superconducting conductor pattern) that is a line-shaped, has one end in contact with an end of the conductor pattern 209a and protrudes toward the SQUID 204 side in an abbreviated U-shape so as to approach the SQUID 204 side, and a line-shaped conductor pattern 209c (superconducting conductor pattern) that is extended from the other end of the an abbreviated U-shaped conductor pattern 209b and on contact with the ground 220. The conductor pattern 209b (the linear conductor closest to the SQUID 204) essentially constitutes an inductor 211 that generates magnetic flux through the loop of the SQUID 204. A gap 221 between the conductor pattern 209c and the first electrode 207-1 substantially constitutes the coupling capacitance 210.

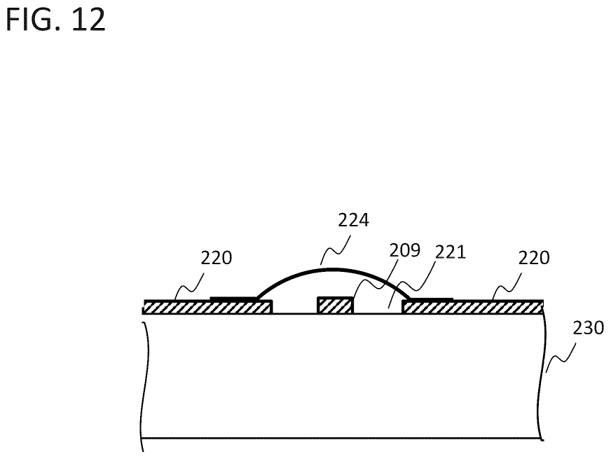

In the examples of FIGS. 11A and 11B, an air bridge 224 is provided to allow a return current in the magnetic flux bias line 209 to flow through the ground 220 on both sides of the magnetic flux bias line 209. FIG. 12 schematically shows a cross-section of the air bridge 224 in FIGS. 11A and 11B. The air bridge 224 strides over the magnetic flux bias line 209 (center conductor) and gaps 221 and connects the ground 220 on both sides. A surface of the substrate 230 is exposed in the gap 221. By allowing the return current of the current flowing in the magnetic flux bias line 209 to flow through the ground 220 on both sides of the magnetic flux bias line 209, an effect of suppressing the generation of unintended resonance modes such as slot line mode and suppressing crosstalk can be expected.

In FIGS. 11A and 11B, a coupling strength between the magnetic flux bias line 209 and the coupler 201 is set to an appropriate value. When the coupling strength between the magnetic flux bias line 209 and the coupler 201 is too weak, it is difficult to measure a resonance of the coupler 201. Conversely, when the coupling strength is too strong, the Q-value of the coupler 201 will decrease. Specifically, the external Q value might be between 10,000 and 100,000 when a signal is supplied to the coupler 201 from the magnetic flux bias line 209 when the resonance frequency of the resonator 206 is set near its maximum value. The external Q value might preferably be in a range between 10,000 and 50,000. It might be further preferred that the external Q value be in a range between 10,000 and 30,000.

In the example illustrated in FIG. 11B, the external Q-value is set to about 18,000, which is within the preferred range according to electromagnetic field simulations. The internal and external Q-values of the coupler 201 may be experimentally measured as follows. First, a reflection coefficient (also called S11) of a signal supplied from the signal source 213 to the coupler 201 is measured with the measuring instrument 214. The reflection coefficient is measured a t different frequencies of the signal. The frequency range of this measurement is set to include the resonance frequency of the coupler 201. The measurement of the reflection coefficient can be performed using a vector network analyzer, for example. By fitting a theoretical equation to the frequency dependence of the reflection coefficient obtained from this measurement, the internal and external Q values of the coupler 201 can be calculated. With the coupler 201, the number of control lines can be reduced to half of the comparative example described with reference to FIG. 8.

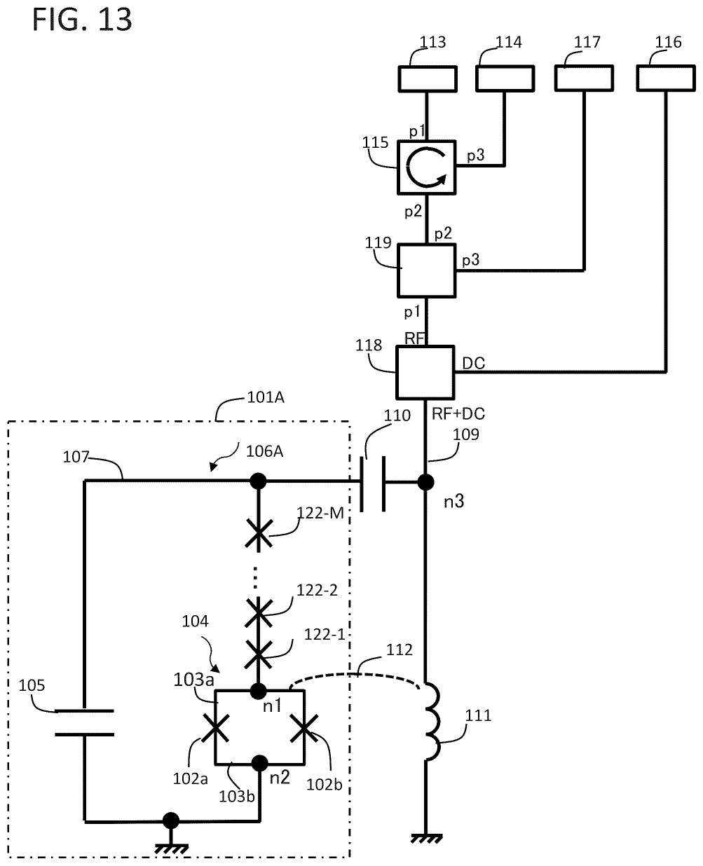

FIG. 13 illustrates qubit 101A, a variant of the qubit 101 in FIG. 4. In FIG. 13, elements identical to those in FIG. 4 are marked with the same reference signs, the description of the same elements is omitted, and differences are described. Referring to FIG. 13, a qubit 101A has a plurality of Josephson junctions 122-1 to 122-M (M is one or more positive integers) connected in series (vertical stacking) between the node n1 and the electrode 107 of the SQUID 104. A shunt capacitor 105 is connected between the electrode 107 and ground in parallel with the series circuit of the SQUID 104 and Josephson junctions 122-1 to 122-M. Critical current values of the Josephson junctions 102a and 102b may be equal or different. By changing critical current values of the Josephson junctions 102a and 102b and changing the number of Josephson junctions 122-1 to 122-M and critical current values thereof, it is possible to set nonlinearity of the qubit 101A to a desired value. Increasing the number of series-connected Josephson junctions 122-1 to 122-M mitigates nonlinearity. The resonance characteristics of the resonator 106A of the qubit 101A can be adjusted. Even in the example of FIG. 13, the number of wirings to be coupled to the qubit 101A can be reduced to half of that in the comparative example. Each operation of control and readout of the qubit 101A is the same as the that described with reference to FIG. 4.

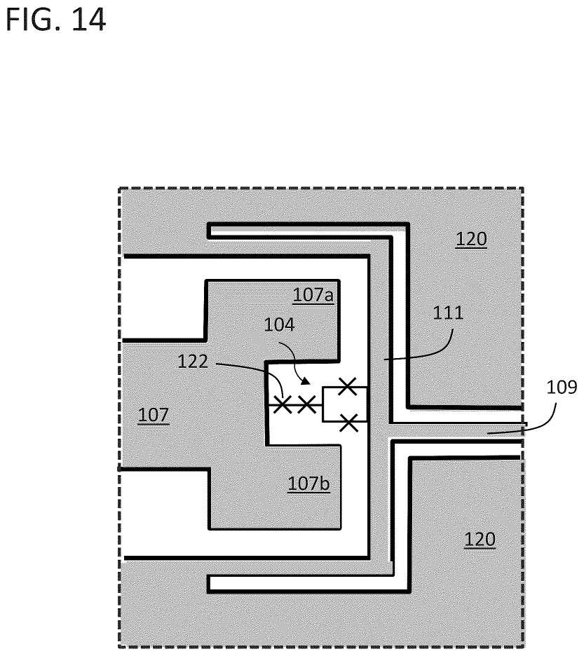

FIG. 14 illustrates an example layout of the qubit 101A in FIG. 13, corresponding to an enlarged view in FIG. 6B. As illustrated in FIG. 14, an inductor 111 connected to ground 120 and a plurality of Josephson junctions 122 in series with SQUID 104 are connected in series in an recess between the electrode tips 107a and 107b.

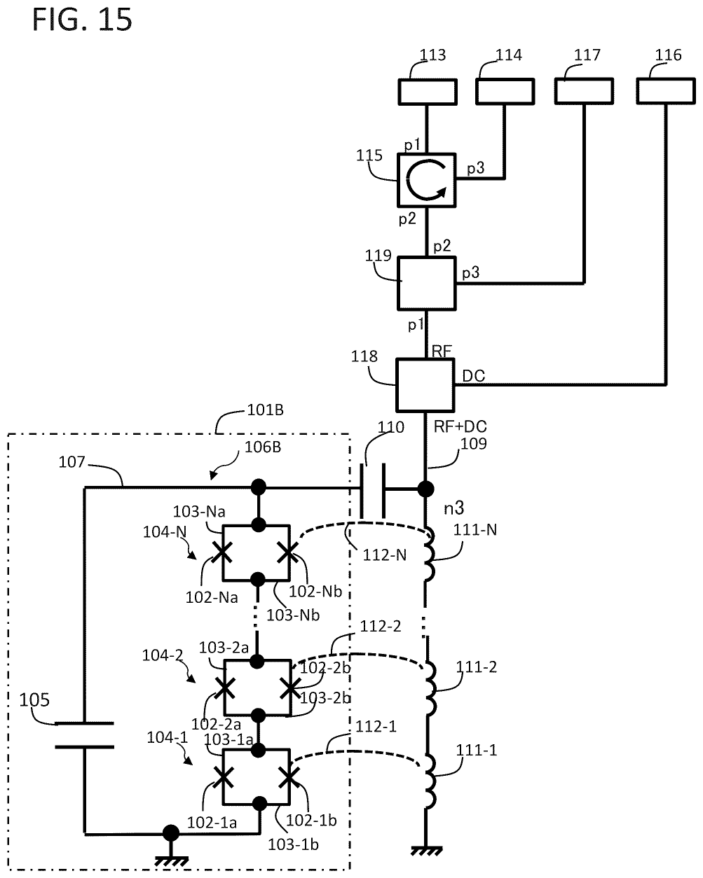

FIG. 15 illustrates another example of the qubit of the present disclosure. In FIG. 15, elements identical to those in FIG. 4 are marked with the same reference signs, the description of the same elements are omitted, and differences are described. Referring to FIG. 15, the resonator 106B of the qubit 101B includes N (N>=2) SQUIDs 104-1 to 104-N connected in series between the electrode 107 and ground and the capacitance 105 connected between the electrode 107 and ground. Critical current values of the Josephson junctions 102-1a to 102-Na and 102-1b to 102-Nb may be equal. Alternatively, at least one may be different, or all may be different.

Between the node n3 at which the control line 109 and the coupling capacitance 110 are connected and ground, N inductors 111-1 to 111-N are connected in series corresponding to each of SQUIDs 104-1 to 104-N. The inductors 111-1 to 111-N and SQUIDs 104-1 to 104-N are magnetically coupled (inductively coupled) through mutual inductance 112-1 to 112-N, respectively. By changing the number of SQUIDs 104-1 to 104-N and the number of the Josephson junctions 102-1a to 102-Na constituting the SQUID and changing critical current values of the Josephson junctions 102-1a to 102-Nb, the nonlinearity of the qubit 101B can be designed to any (desired) value. In the configuration of FIG. 15, the number of control lines coupled to the qubits 101B can also be reduced to half of the comparative example described with reference to FIG. 1. The operation of the control and readout of the qubit 101B is identical to the example of FIG. 4.

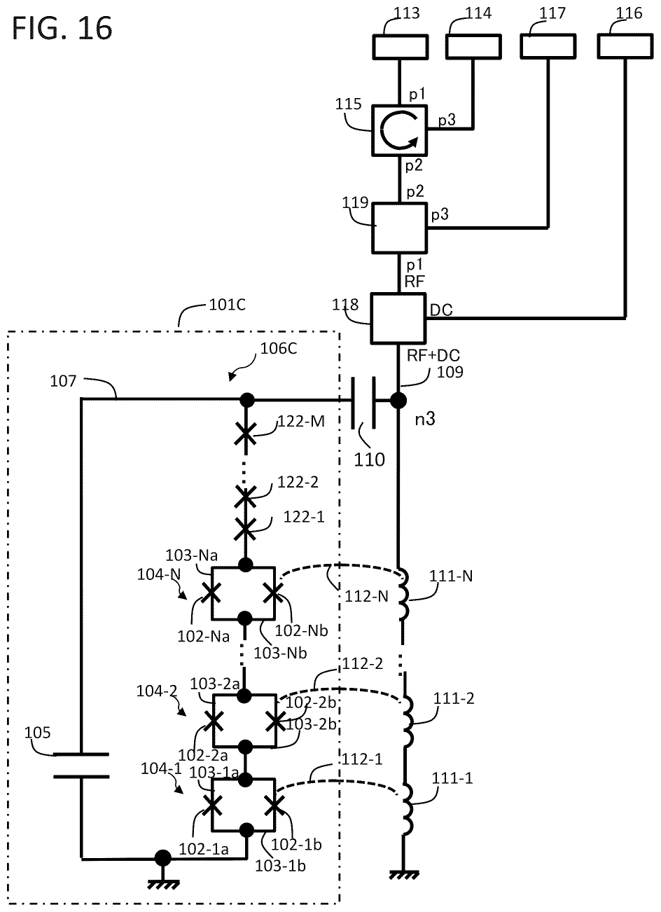

FIG. 16 illustrates yet another example of the qubit of the present disclosure. In FIG. 16, elements identical to those in FIG. 15 are marked with the same reference signs, the description of the same elements is omitted, and differences are described. Referring to FIG. 16, a qubit 101C includes a plurality of Josephson junctions 122-1 to 122-M (M is one or more positive integers) connected in series between the superconducting members 103-Na and the electrode 107 of the SQUID 104-N in the configuration of FIG. 15. The capacitance 105 is connected in parallel with the series circuit of N SQUIDs 104-1 to 104-N and M Josephson junctions 122-1 to 122-M, between the electrode 107 and ground. With a change of the number of the SQUIDs 104-1 to 104-N, the critical current values of the Josephson junctions 102-1a to 102-Na and Josephson junctions 102-1b to 102-Nb, and the number and critical current values of Josephson junctions 122-1 to 122-M, the nonlinearity of the qubit 101C can be designed to any (arbitrary) value. The number of the control lines can be reduced to half of the comparative example described with reference to FIG. 1. The operation of control and readout of the qubit 101C is identical to the example described with reference to FIG. 4.

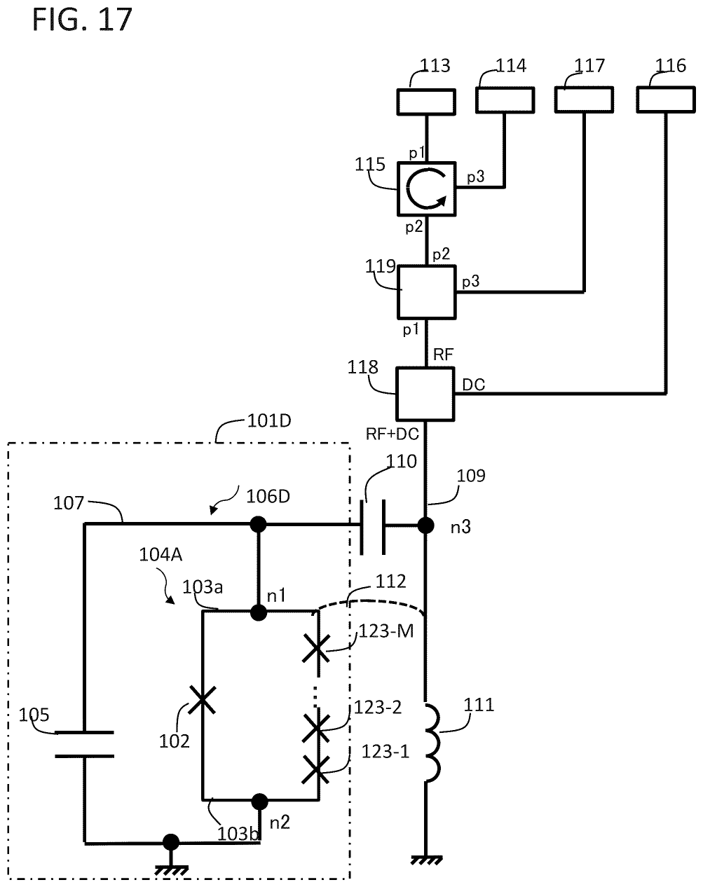

FIG. 17 illustrates yet another example of the qubit of the present disclosure. In FIG. 17, elements identical to those in FIG. 4 are marked with the same reference signs, and with the description of the same elements being omitted; differences will be described. Referring to FIG. 17, a qubit 101D included in resonator 106D differs from the configuration of the configuration of the SQUID 104A of FIG. 4. In the SQUID 104A, one Josephson junction 102 and M (M>=2) Josephson junctions 123-1 to 123-M connected in series form are connected in parallel between node the node connected to the electrode 107 and the node n2 connected to ground. In the array with Josephson junctions 123-1 to 123-M connected in series, let a phase difference between the two ends of the array (between the nodes n1 and n2) be γ1, the phase difference at the Josephson junction 102 γ2, and the magnetic flux be through the loop of the SQUID 104A Φ and the magnetic flux quantum be Φ0, the following holds

$${γ}_{2} = {γ}_{1} + 2 π Φ / {Φ}_{0} + 2 m π , ( m = 0 , \pm 1 , \pm 2 , … ) \qquad ( 14 )$$

When the array of Josephson junctions 123-1 to 123-M consists of identical Josephson junctions, a phase difference γ₁/M, which is the phase difference γ₁ divided equally, is a phase difference between the input and output at each Josephson junctions 123-1 to 123-M. The potential energy of the first series-connected Josephson junctions 123-1 to 123-M is an individual potential energy

$$- {E}_{J} cos ( {γ}_{1} / M ) \qquad ( 15 )$$

and is given by adding up M potential energies

$$- M \times {E}_{J} cos ( {γ}_{1} / M ) \qquad ( 16 )$$

where E_{J} is the Josephson energy.

$${E}_{J} = ( h / 2 π ) 1 / 2 e {I}_{C} \qquad ( 17 )$$

(h is a Planck's constant, e is the elementary charge, and I_{C} is a critical current)

The critical current values of the Josephson junction 102 and Josephson junctions 123-1 to 123-M may be set equal or different. By changing the number and critical current values of the Josephson junctions 123-1 to 123-M and the critical current value of the Josephson junction 102, a nonlinearity of the qubit 101D can be designed to any value.

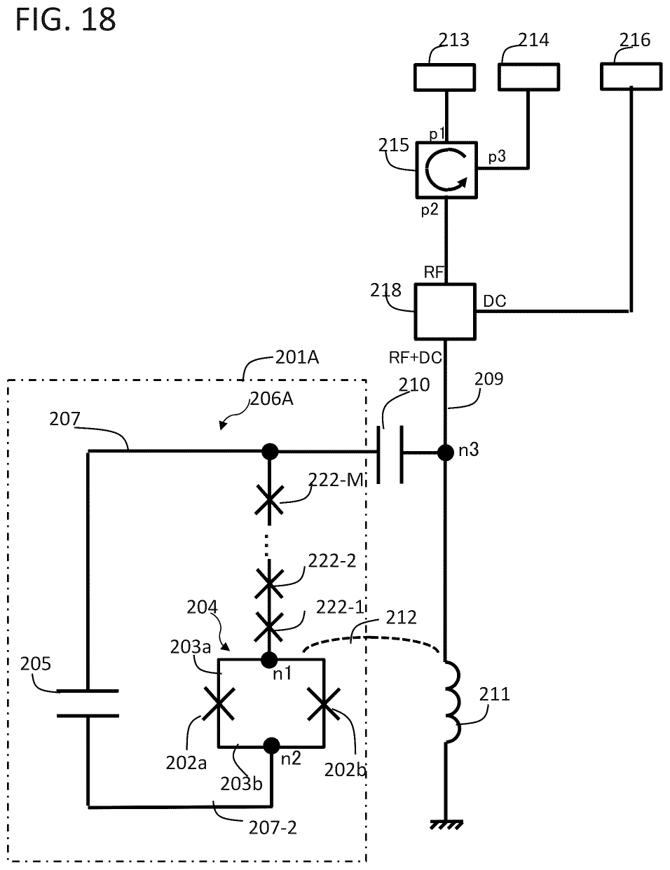

FIG. 18 illustrates another example of a coupler of the present disclosure. In FIG. 18, the same elements as in FIG. 10 are marked with the same reference signs, the description of the same elements is omitted, and the differences are described. As the coupler 201A, a plurality of the Josephson junctions 222-1 to 222-M (M is one or more positive integers) are connected in series (vertically stacked) between the node n1 and the electrode 207 of the SQUID 204. The capacitance 205 is connected between the electrode 207 and ground in parallel with the series circuit of the SQUID 204 and Josephson junctions 222-1 to 222-M. The critical current values of the Josephson junctions 202a and 202b may be made equal or different from each other. By changing the critical current values of the Josephson junctions 202a and 202b and the number of Josephson junctions 222-1 to 222-M and their critical current values, it is possible to set the nonlinearity of the coupler 201A to a desired value. Thus, the resonance characteristics of the resonator 206A can be adjusted. Even in the example of FIG. 18, the number of wires to be coupled to the coupler 201A can be reduced to half of the comparative example described with reference to FIG. 8. The operation of controlling and reading out the coupler 201A is identical to the example described with reference to FIG. 10.

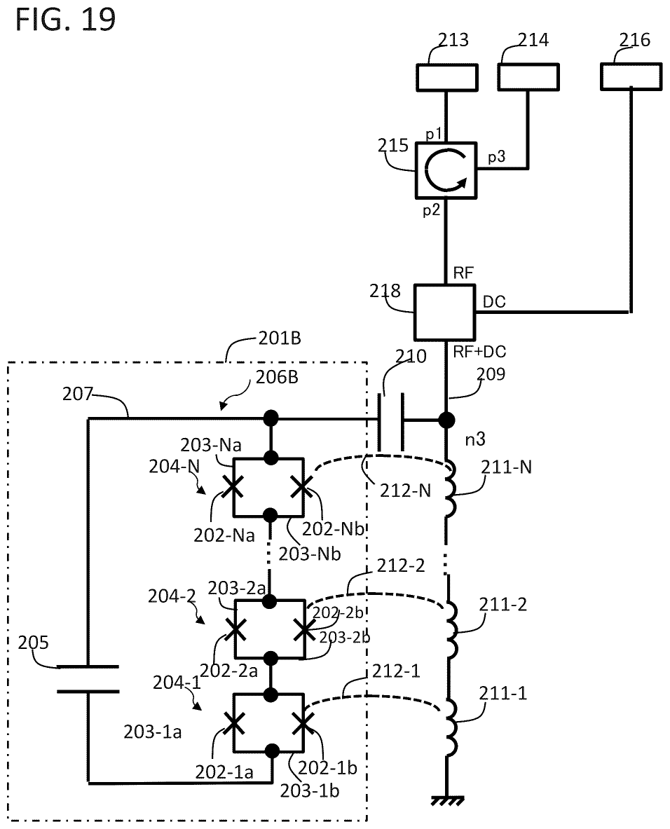

FIG. 19 illustrates another example of a coupler of the present disclosure. In FIG. 19, the same elements as in FIG. 10 are marked with the same reference signs, the description of the same elements is omitted, and the differences are described. The resonator 206B of the coupler 201B includes N (N>=2) SQUIDs 204-1 to 204-N connected in series between the electrode 207 and ground and the capacitance 205. The critical current values of the Josephson junctions 202-1a to 202-Na and 202-1b to 202-Nb may be equal. Alternatively, at least one of the Josephson junctions 202-1a to 202-Na and 202-1b to 202-Nb may be different, and there may be configurations in which all of the Josephson junctions 202-1a to 202-Na and 202-1b to 202-Nb are different. Between the node n3 at which the control line 209 and the coupling capacitance 210 are connected and ground, there are provided N inductors 211-1 to 211-N connected in series corresponding to SQUIDs 204-1 to 204-N, respectively. The inductors 211-1 to 211-N and SQUIDs 204-1 to 204-N, respectively are electro-magnetically connected by mutual inductances 212-1 to 212-N. By changing the number of the SQUIDs 204-1 to 204-N and the critical current values of the Josephson junctions 202-1a to 202-Na and 202-1b to 202-Nb composing the SQUID, the nonlinearity of the coupler 201B can be designed to any (desired) value. In the configuration of FIG. 19, the number of control lines coupled to the coupler 201B can also be reduced to half that of the comparative example described with reference to FIG. 8. The operation of control and readout of the coupler 201B is identical to the example described with reference to FIG. 10.

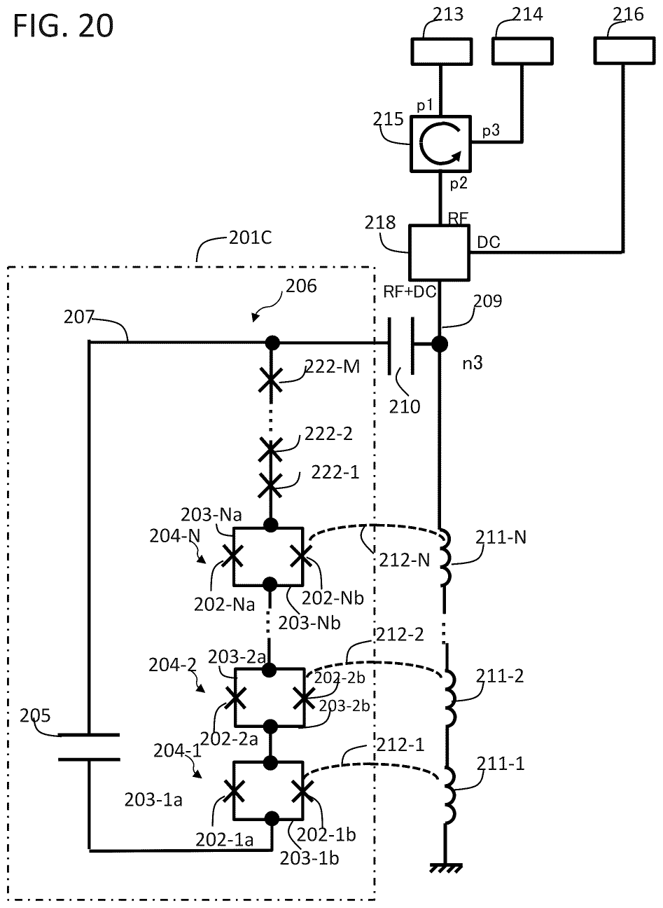

FIG. 20 illustrates yet another example of a coupler of the present disclosure. In FIG. 20, the same elements as in FIG. 19 are marked with the same reference signs, the description of the same elements is omitted, and the differences are described. Referring to FIG. 20, there are provided between the superconducting member 203-Na and the electrode 207 of the SQUID 204-N in the configuration of FIG. 19, a plurality of Josephson junctions 222-1 to 222-M (M is one or more positive integers). The capacitance 205 is connected in parallel with a series circuit of N SQUIDs 204-1 to 204-1-N and M Josephson junctions 222-1 to 222-M, between the electrode 207 and ground. By changing the number of SQUIDs 204-1 to 204-N and critical current values of the Josephson junctions 202-1a to 202-Na and Josephson junctions 202-1b to 202-Nb that compose the SQUIDs and changing the critical current values of the Josephson junctions 202-1b to 202-Nb and the number of Josephson junctions 222-1 to 222-M, nonlinearity of the coupler 201C can be designed to any desired value. The number of the control lines to be coupled to the coupler 201C can be reduced to half of the comparative example with reference to FIG. 8. The control and readout operation of the coupler 201C is identical to the example with 20 reference to FIG. 10.

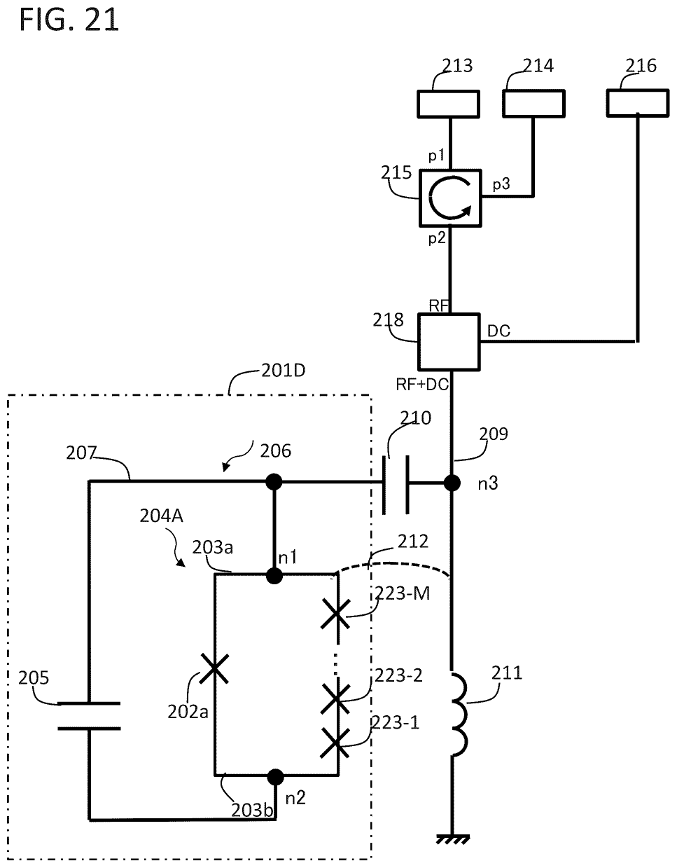

FIG. 21 illustrates yet another example of a coupler of the present disclosure. In FIG. 21, elements identical to those in FIG. 10 are marked with the same reference signs, the description of identical elements is omitted, and differences are described. Referring to FIG. 21, the coupler 201D differs in the configuration of SQUID 204A of FIG. 10. In the SQUID 204D, one Josephson junction 202a, and M (M>=2) SQUIDs 223-1 to 223-M connected in series are connected in parallel between the node n1 connected to the electrode 207 and the node n2 connected to ground. The SQUID 204D corresponds to SQUID 204D of the qubit 101D in FIG. 17. The critical current values of the Josephson junction 202A and the Josephson junctions 223-1 to 223-M may be made equal or different. By changing the number M and critical current values of the Josephson junctions 223-1 to 223-M and the critical current value of the Josephson junction 202a, the nonlinearity of the coupler 201D can be designed to any value. The number of control lines to be coupled to the coupler 201D can be reduced to half of the comparative example with reference to FIG. 8. The operation of control and readout of the coupler 201D is identical to the example with reference to FIG. 10.

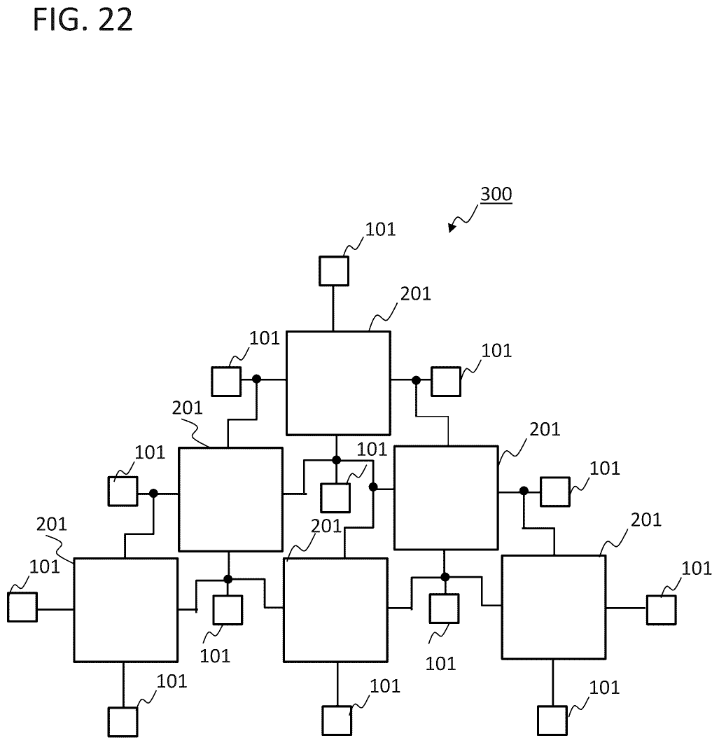

FIG. 22 schematically illustrates a n example configuration of a superconducting quantum computer 300 (quantum annealing machine). In the example of FIG. 22, each coupler 201 couples four adjacent qubits 101 with a four-body interaction. The coupler 201 and the four adjacent qubits 101 are referred to as a unit structure (also called Plaquette) (Reference Literature 3). In the superconducting quantum computer 300, at least one qubit 101 is connected to a plurality of couplers 201. In the example shown in FIG. 22, the superconducting quantum computer 300 has multiple unit structures and the qubit 101 is shared by multiple unit structures. In FIG. 22, 13 qubits 101 are integrated, but any number of qubits may be integrated in a similar manner. In FIG. 22, the signal source and readout sections are omitted. The configuration of FIG. 22 is considered suitable for LHZ (Lechner, Hauke, Zoller) networks, which is one of quantum annealing schemes.

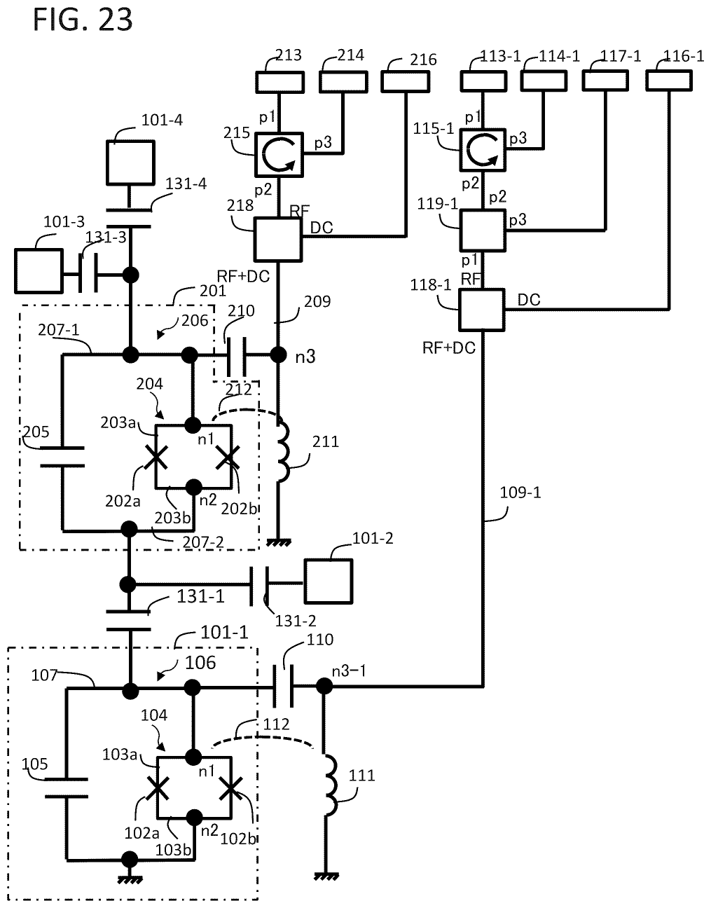

FIG. 23 schematically illustrates the connection of the coupler 201 of FIG. 22 and the four qubits 101-1 to 101-4 adjacent (most proximate) to the coupler 201. In FIG. 23, for convenience of drawing, only qubit 101-1 out of the four qubits 101-1 to 101-4 and the control line 109-1 (inductor 111), signal source 113-1, measuring instrument 114-1, DC power supply 116-1, and AC power supply 117-1 are shown. For the remaining qubits 101-2 to 101-4, the connection configuration is the same as with the qubit 101-1. The electrode 107 of the qubit 101-1 is capacitively coupled via a capacitor 131-1 to the electrode 207-2 of the coupler 201. The electrode of qubit 101-2 is also capacitively coupled via a capacitor 131-2 to the electrode 207-2 of the coupler 201. The electrodes of the qubits 101-3 and 101-4 are also capacitively coupled via capacitors 131-3 and 131-4 to the electrode 207-1 of the coupler 201. In this configuration, conditions for the four qubits 101-1 to 101-4 to perform four-body interaction through the coupler 201 are as follows. Let the resonance frequencies of the qubits 101-1 to 101-4 be Φ1 to Φ4, respectively, and the resonance frequency of the coupler 201 be or, with assumption that the qubits 101-1 to 101-4 and the coupler 201 are detuned from each other,

$$ω 1 + ω 2 = ω 3 + ω 4 \qquad ( 18 )$$

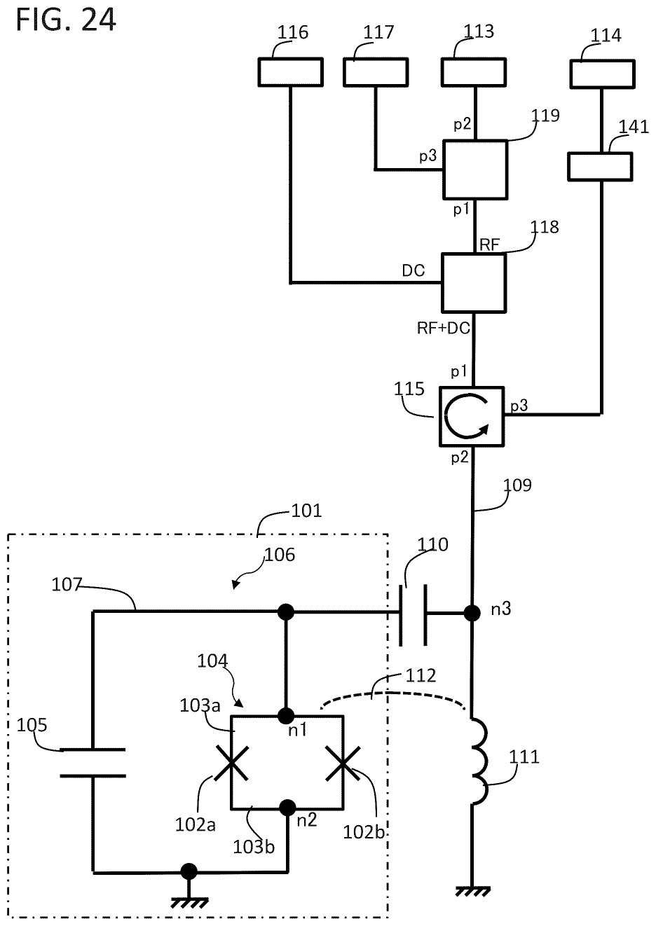

FIG. 24 schematically illustrates a variation example of FIG. 4. Referring to FIG. 24, in this variation, the port 1 (p1) of the circulator 115 is connected to the RF+DC port of the bias T circuit 118, the port 2 (p2) of the circulator 115 is connected to the control line 109, and the port 3 (p3) of the circulator 115 is connected to the measuring instrument 114. An AC signal from the signal source 113 is supplied to the port 1 (p1) of the circulator 115 via the diplexer 119 (port 3 (p3) is connected to the output of AC power supply 117) and the bias T circuit 118 (DC port is connected to the output of DC power supply 116), and propagates in one direction from the port 1 (p1) for output from the port 2 (p2) of the circulator 115. The signal output from the port 2 (p2) of the circulator 115 to the control line 109 (AC signal from AC power supply 117 and/or signal source 113) is supplied from the control line 109 to the qubit 101 via the coupling capacitance 110. The signal (AC signal+DC signal) output from the port 2 (p2) of the circulator 115 to control line 109 flows into the inductor 111 to generates a magnetic flux that penetrates SQUID 104 of the qubit 101. The signal from the qubit 101 (output/reflected signal) propagates via the coupling capacitance 110 to the control line 109, is supplied to the port 2 (p2) of the circulator 115, propagates in one direction from the port 2 (p2), is output from the port 3 (p3) of the circulator 115, and transmitted through a filter 141 to the measuring instrument 114. As described above, the output from the port 3 (p3) of the circulator 115 is transmitted through an unshown low-pass filter, band-pass filter, isolator, HEMT amplifier, etc., to the measuring instrument 114 outside the refrigerator not shown. The filter 141 (low-pass filter or band-pass filter) is designed to allow the reflected signal (angular frequency: Φ0) at the qubit 101 corresponding to the AC signal from the signal source 113, among the reflected signals from the qubit 101 proceeding from port 2 (p2) to port 3 (p3) of the circulator 115, to pass therethrough and block the reflected signal (angular frequency: approximately 2×ω0) at the qubit 101 for the AC signal from the AC power source 117, thus supplying the reflected signal (e.g., angular frequency: ω0) at the qubit 101 to the measuring instrument 114.

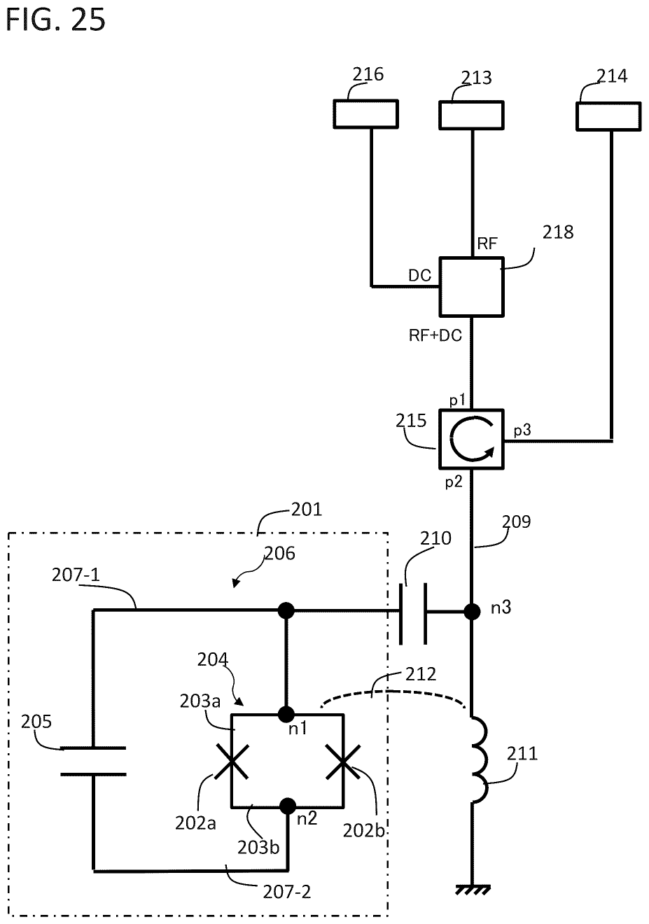

FIG. 25 schematically illustrates a variation example of FIG. 10. Referring to FIG. 25, in this variation, the port 1 (p1) of the circulator 215 is connected to the RF+DC port of the bias T circuit 218, the port 2 (p2) of the circulator 215 is connected to the magnetic flux bias line 209, and the port 3 (p3) of the circulator 215 is connected to the measuring instrument 214. The AC signal from the signal source 213 is supplied to the port 1 (p1) of the circulator 215 through the bias T circuit 218 (DC port is connected to the output of DC power supply unit 216) and proceeds in one direction from the port 1 (p1) to the port 2 (p2) of the circulator 215. The signal (AC signal) output from the port 2 (p2) of the circulator 215 to magnetic flux bias line 209 is supplied from magnetic flux bias line 209 to the coupler 201 via the coupling capacitance 210. The signal (AC signal+DC signal) output from the port 2 (p2) of the circulator 215 to the magnetic flux bias line 209 flows into the inductor 211 to generate a magnetic flux that penetrates the SQUID 204 of the coupler 201. The signal (output signal/reflected signal) from the coupler 201 propagates via the coupling capacitance 210 to the magnetic flux bias line 209, is supplied to the port 2 (p2) of the circulator 215, proceeds in one direction from the port 2 (p2) to the port 3 (p3) and transmitted therefrom to the measuring instrument 214.

The above example embodiments may be following Notes (but not limited supplemented as thereto).

(Note 1) A superconducting quantum circuit apparatus includes a qubit; and a first wiring with a wiring used as a transmission of a signal to generate a magnetic flux to be applied to the qubit and a wiring used as a transmission of a signal input by capacitive coupling to and/or output, by capacitive coupling from the qubit combined together thereinto as a single wiring.

(Note 2) The superconducting quantum circuit apparatus of Note 1, includes a first inductor, wherein the qubit includes:
a first node;
a second node connected to ground;
at least one Josephson junction between the first node and the second node;
a first electrode connected to the first node; and
a first capacitor connected between the first electrode and the ground, wherein the first wiring is connected via the first inductor to the ground and connected via a coupling capacitor to the first electrode.

(Note 3) In the superconducting quantum circuit apparatus of Note 2, in the qubit, when operated,
the first SQUID is applied with a magnetic field generated by a current signal fed from the first wiring to the first inductor;
a current signal fed from the first wiring is supplied via a coupling capacitor to the qubit, and
a signal from the qubit is via the coupling capacitor propagated to the first wiring and read-out.

(Note 4) In the qubit of the superconducting quantum circuit apparatus of Note 2 or 3, one Josephson junction or a plurality of Josephson junctions connected in series between the first node and the first electrode of the first SQUID is further included.

(Note 5) In the qubit of the superconducting quantum circuit apparatus of Note 2, there is provided at least one second SQUID connected in series with the first SQUID between the first electrode and the ground. The at least one second SQUID includes at least one Josephson junction between a first node and a second node of the at least one second SQUID. The second node of the at least one second SQUID is connected to a neighboring first SQUID or a first node of neighboring second SQUID. The first node of the at least one second SQUID is connected to the second node of a neighboring second SQUID or to the first electrode. Between one end of the first wiring and the first inductor is provided at least one second inductor coupled to the at least one second SQUID via a mutual inductance.

(Note 6) In the qubit of the superconducting quantum circuit apparatus of Note 5, the first node of the second SQUID is connected to the first electrode via at least one second SQUID, or one Josephson junction, or multiple Josephson junctions connected in series.

(Note 7) In the qubit of the superconducting quantum circuit apparatus of Note 2, the first SQUID is connected to the first SQUID between the first node and the second node via at least one the first Josephson junction connected in parallel with each other and a plurality of the second Josephson junctions connected in series. The first Josephson junction and the second Josephson junction are connected in series.

(Note 8) In the superconducting quantum circuit apparatus of Note 2, the first wiring is connected from a contact with the ground to an expanded wiring opposite the end of the first electrode, the end of the first electrode of the qubit is expanded in a width thereof, and at least a portion of the expanded wiring opposite the end of the first electrode is connected to the end of the first electrode of the qubit. At least a portion of the expanded wiring opposite to the expanded end of the first electrode and an opposing edge of the first electrode opposite at least a portion of the wiring through a gap form the coupling capacitor, and the first SQUID of the qubit bridges the end of the first electrode and the ground end of the first electrode. At least a portion of the wiring extended opposite the end of the first electrode acts as the first inductor.

(Note 9) The superconducting quantum circuit apparatus of any of Notes 1-8, a first signal source for generating an AC signal to be applied to the qubit of the superconducting circuit by capacitive coupling, a second signal source for generating an AC signal to be applied to the qubit by inductive coupling, a third signal source for generating a DC signal to be applied by inductive coupling to the qubit, a diplexer configured to combine signals from the first signal source and the second signal source for output, and a bias circuit outputting a signal biased by the DC signal from the third signal source at the output of the diplexer, wherein the signal from the bias circuit is fed to the first wiring and a signal from the qubit propagates to the first wiring. There is provided a first measuring instrument configured to receive a signal branched by a circulator from a path from the first signal source to the first wiring.

(Note 10) In the superconducting quantum circuit apparatus of any of Notes 1 to 8, includes a coupler configured to mutually couple a plurality of qubits including at least the qubit as set forth in any of Notes 1 to 8, a second wiring with a wiring used as a transmission of a signal to generate a magnetic flux to be applied to the coupler and a wiring used as a transmission of a signal input by capacitive coupling to and/or output, by capacitive coupling from the coupler, combined together thereinto as a single wiring.

(Note 11) In the superconducting quantum circuit apparatus of Note 10, the coupler includes a first SQUID including at least a first Josephson junction and a second Josephson junction connected in parallel with each other between a first electrode and a second electrode of the coupler and a first capacitor connected between the first and second electrode. The second wiring is connected to ground via the first inductor for the coupler and to the first electrode or the second wiring via the coupling capacitor for the coupler.

(Note 12) In the superconducting quantum circuit apparatus of Note 10 or 11, in the coupler, during operation, the current flowing from the second wiring to the first inductor for the coupler generates a magnetic field that penetrates the first SQUID of the coupler. A signal from the second wiring is supplied to the coupler via the coupling capacitor for the coupler, and the signal from the coupler is propagated to the second wiring via the coupling capacitor for the coupler and read out.

(Note 13) The coupler of the superconducting quantum circuit apparatus of Note 11, further includes one Josephson junction or a plurality of Josephson junctions connected in series between the first node of the first SQUID of the coupler and the first electrode of the coupler.

(Note 14) In the coupler of the superconducting quantum circuit apparatus of Note 11, there is provided at least one second SQUID connected in series with the first SQUID between the first electrode and the second electrode of the coupler. The second SQUID includes at least a first Josephson junction and a second Josephson junction connected in parallel with each other between a first node and a second node of the second SQUID. The second node of the second SQUID is connected to the second node of a neighboring second SQUID or to the first electrode. There is provided between the second wiring and the first inductor for the coupler, at least one second inductor for the coupler configured to couple with the at least one second SQUID via a mutual inductance.

(Note 15) In the coupler of the superconducting quantum circuit apparatus of Note 11, the first node of the second SQUID is connected to the second node of a neighboring second SQUID or to the first electrode via a single Josephson junction or a plurality of Josephson junctions connected in series. The second node is connected to the first electrode via a single Josephson junction or multiple Josephson junctions connected in series.

(Note 16) In the coupler of the superconducting quantum circuit apparatus of Note 11, the first SQUID of the coupler includes at least one the first Josephson junction connected in parallel with each other between the first and second nodes of the first SQUID and a plurality of the second Josephson junctions connected in series.

(Note 17) The superconducting quantum circuit apparatus of Note 10, includes a fourth signal source configured to generate an AC signal to be applied capacitively coupled to the coupler of the superconducting circuit, a fifth signal source configured to generate a DC signal to be applied via inductive coupling to the coupler, and a bias circuit configured to bias the output of the fourth signal source with the DC signal from the fifth signal source. The bias circuit is connected to the second wiring. There is provided a second measuring instrument configured to receive a signal that propagates from the coupler to the second wiring and is split by a circulator from a path from the fourth signal source to the second wiring.

[Reference Literature 1] Unexamined Patent Publication No. 2021-108308

[Reference Literature 2] “Progress and Applications of Superconducting Qubit Research”, Yasunobu Nakamura, Applied Physics, 2021, Vol. 90, No. 4 p. 209-220 [retrieved on Jan. 16, 2024] (Internet <URL>https://www.jstage.jst.go.jp/article/oubutsu/90/4/90_209/_pdf/-char/ja)

[Reference Literature 3] S. Puri, et al. “Quantum annealing with all-to-all connected nonlinear oscillators,” Nature Communications. June 2017.

The disclosures in Patent Document 1 and References 1-3 above shall be incorporated herein by reference. Within the framework of the entire disclosure (including the scope of claims), furthermore, based on the basic technical concept, changes and adjustments to the embodiments or examples are possible. In addition, various combinations and selections of various disclosed elements (including each element of each Note, each element of each example, each element of each drawing, etc.) are possible within the framework of the claims of the disclosure. In other words, the disclosure invention includes, of course, various transformations and modifications that a person skilled in the art would be able to make in accordance with the entire disclosure including the claims and the technical concept.

What is claimed is:

1. A superconducting quantum circuit apparatus comprising:
a qubit; and
a first wiring with a wiring used as a transmission of a signal to generate a magnetic flux to be applied to the qubit and a wiring used as a transmission of a signal input by capacitive coupling to and/or output, by capacitive coupling from the qubit, combined together thereinto, as a single wiring.

2. The superconducting quantum circuit apparatus according to claim 1, comprising
a first inductor,
wherein the qubit includes:
a first SQUID (Superconducting Quantum Interference Device) including a first node;
a second node connected to ground; and
at least one Josephson junction between the first node and the second node;
a first electrode connected to the first node; and
a first capacitor connected between the first electrode and the ground,
wherein the first wiring is connected via the first inductor to the ground and connected via a coupling capacitor to the first electrode.

3. The superconducting quantum circuit apparatus according to claim 1, wherein, in the qubit, in operation,
the first SQUID is applied with a magnetic field generated by a current signal fed from the first wiring to the first inductor;
a current signal fed from the first wiring is supplied via a coupling capacitor to the qubit, and
a signal from the qubit is via the coupling capacitor propagated to the first wiring and read-out.

4. The superconducting quantum circuit apparatus according to claim 2, wherein the qubit includes
one Josephson junction or a plurality of Josephson junctions connected in series between the first node of the first SQUID and the first electrode.

5. The superconducting quantum circuit apparatus according to claim 2, wherein the first wiring is connected to a wiring that is extended from a contact portion with the ground along an end portion of the first electrode of the qubit,
the first electrode of the qubit has a width of the end portion widened,
at least a portion of the wiring extended and opposite the widened end portion of the first electrode and an opposing edge of the first electrode opposite at least the first portion of the wiring via gap constitute a coupling capacitor,
the first SQUID of the qubit bridges an edge of the first electrode and an edge of the ground, and
at least a portion of the wiring extended opposite the end portion of the first electrode constitutes the first inductor.

6. The superconducting quantum circuit apparatus according to claim 2, wherein the qubit comprises
at least one second SQUID connected in series with the first SQUID between the first electrode and ground, and wherein
the superconducting quantum circuit apparatus comprises
at least one second inductor coupled to the at least one second SQUID via a mutual inductance between one end of the first wiring and the first inductor.

7. The superconducting quantum circuit apparatus according to claim 2, wherein the qubit comprises a second SQUID with a first node thereof connected to the first electrode via at least another second SQUID, and/or one Josephson junction or multiple Josephson junctions connected in series.

8. The superconducting quantum circuit apparatus according to claim 2, wherein the first SQUID includes, between the first node and the second node of thereof, at least one first Josephson junction and a plurality of second Josephson junctions connected in parallel with the at least one first Josephson junction, the plurality of second Josephson junctions connected in series.

9. The superconducting quantum circuit apparatus according to claim 1, including
a first signal source configured to generate an AC signal applied by capacitive coupling to the qubit;
a second signal source configured to generate an AC signal applied by inductive coupling to the qubit;
a third signal source configured to generate a DC signal applied by inductive coupling to the qubit;
a diplexer configured to combine the signals from the first and second signal sources to output, as an output signal, the combined signal; and
a bias circuit configured to output a signal composed of the output signal from the diplexer biased by the DC signal from the third signal source, the signal from the bias circuit being supplied to the first wiring,
wherein the superconducting quantum circuit apparatus further comprising a first measurement instrument configured to receive a signal propagated from the qubit to the first wiring and split by a circulator arranged on a path from the first signal source to the first wiring.

10. The superconducting quantum circuit apparatus according to claim 1, further comprising
a coupler configured to mutually couple a plurality of qubits including at least the qubit,
a second wiring with a wiring used as a transmission of a signal to generate a magnetic flux to be applied to the coupler and a wiring used as a transmission of a signal input by capacitive coupling to and/or output, by capacitive coupling from the coupler, combined together thereinto as a single wiring.

11. The superconducting quantum circuit apparatus according to claim 10, further comprising
a second inductor,
wherein the coupler includes:
a second SQUID including:
a first node;
a second node connected to ground; and
at least one Josephson junction between the first node and the second node of the second SQUID;
a second electrode connected to the first node of the second SQUID; and
a second capacitor connected between the first electrode of the second SQUID and the ground,
wherein the second wiring is connected via the second inductor to the ground and connected via a second coupling capacitor to the second electrode.

12. The superconducting quantum circuit apparatus according to claim 1, wherein, in the qubit, when operated,
the first SQUID is applied with a magnetic field generated by a current signal fed from the first wiring to the first inductor;
a current signal fed from the first wiring is supplied via a coupling capacitor to the qubit, and
a signal from the qubit is via the coupling capacitor propagated to the first wiring and read-out.

13. The superconducting quantum circuit apparatus according to claim 10, further comprising:
a fourth signal source configured to generate an AC signal to be applied by capacitive coupling to the coupler;
a fifth signal source configured to generate a DC signal to be applied inductively coupled to said coupler;
a bias circuit to bias an output signal from the fourth signal source with the DC signal from the fifth signal source, the bias circuit connected to the second wiring; and
a second measuring instrument configured to receive a signal propagating from the coupler to the second wiring and split from a path from the fourth signal source to the second wiring.
